(19) United States
(12) Patent Application Publication
(10) Pub. No.: US 2006/0068222 A1
(43) Pub. Date: Mar. 30, 2006

(54) Organic electroluminescent device

(75) Inventors: Yoshitaka Kitamura, Minami-ashigara-shi (JP); Masayuki Mishima, Minami-ashigara-shi (JP)

Correspondence Address: BIRCH STEWART KOLASCH & BIRCH, PO BOX 747, FALLS CHURCH, VA, 22040-0747, US

(73) Assignee: Fuji Photo Film Co., Ltd.

(21) Appl. No.: 11/234,273

(22) Filed: Sep. 26, 2005

(30) Foreign Application Priority Data
Sep. 27, 2004 (JP) 2004-279563

(51) Int. Cl. H01L 51/54; H05B 33/14

(52) U.S. Cl. 428/690; 428/917; 313/504; 313/506; 257/E51.044

(57) ABSTRACT

An organic electroluminescent device having an anode, a cathode, and at least one organic-compound layer that is provided between the anode and the cathode, with at least one layer of the at least one organic-compound layer being an organic luminescent layer, wherein the organic luminescent layer contains at least one host material and at least two luminescent materials, and at least one of the luminescent materials is a metal complex having a tridentate or higher polydentate chain ligand.

### FIELD OF THE INVENTION

The present invention relates to organic electroluminescent devices that can convert electric energy into light. The present invention specifically relates to an organic electroluminescent device improved in external quantum effect, color purity, and durability.

### BACKGROUND OF THE INVENTION

An organic electroluminescent device using an organic substance has good prospects for use for a solid-state-luminescent-type, inexpensive, large-area, full-color display device; and, a write light source array, and many applications of the organic electroluminescent device are being developed in several directions. Generally, the organic electroluminescent device is composed of a luminescent layer, and a pair of opposite electrodes between which the luminescent layer is inserted. When an electric field is applied between both electrodes, an electron is injected from the cathode, and a hole is injected from the anode. Electron emission is a phenomenon in which an electron and a hole are re-combined in the luminescent layer, and the electron emits energy as light when it returns from a conduction band to a valence band.

A conventional organic electroluminescent device has defects that the driving voltage is high and luminance and luminous efficiency are low. In recent years, however, a variety of technologies have been presented to resolve such defects.

For example, JP-A-2003-68466 (“JP-A” means unexamined published Japanese patent application) discloses an electroluminescent device having an anode and a cathode formed on a substrate, and an organic luminescent layer placed between the anode and the cathode; the organic luminescent layer contains a host material and a dopant added to the host material, the dopant being a luminescent material and a non-luminescent compound. The device enables low-voltage driving, high luminance, high efficiency, and high durability.

JP-A-2003-77674 discloses an electroluminescent device comprising a luminescent layer to which are added (1) a host material having an electron-transporting and/or hole-transporting property, (2) Compound A showing phosphorescence emission at room temperature, and (3) Compound B showing phosphorescence emission or fluorescence emission at room temperature, and having its maximum emission wavelength longer than the maximum emission wavelength of Compound A, thereby making Compound B emit at high efficiency. That is to say, Compound B is a phosphorescent compound that does not emit at high efficiency by itself, or a fluorescent compound that exhibits different types of emission colors but does not exhibit as high a luminous efficiency as a phosphorescent compound. By using Compound A showing phosphorescence emission at room temperature, which compound is the constituent feature (2), together with Compound B, Compound A plays a role as a sensitizer, thereby strengthening the emission of Compound B.

While such an organic electroluminescent device as above described is disclosed, further improvement has been required in its luminous efficiency and durability.

For an organic electroluminescent device, many applications for various types of displays have been expected, one of which is an application for a vehicle-mounted display. In such a case, high durability and long use life of the device inside a car, at high temperatures are required.

### SUMMARY OF THE INVENTION

The present invention resides in an organic electroluminescent device comprising an anode, a cathode, and at least one organic-compound layer that is provided between the anode and the cathode, with at least one layer of the at least one organic-compound layer being an organic luminescent layer, wherein the organic luminescent layer comprises at least one host material and at least two luminescent materials, and at least one of the luminescent materials is a metal complex that has a tridentate or higher polydentate chain ligand.

Other and further features and advantages of the invention will appear more fully from the following description.

### DETAILED DESCRIPTION OF THE INVENTION

According to the present invention, there is provided the following means:

<1> An organic electroluminescent device comprising an anode, a cathode, and at least one organic-compound layer that is provided between the anode and the cathode, with at least one layer of the at least one organic-compound layer being an organic luminescent layer,

wherein the organic luminescent layer comprises at least one host material and at least two luminescent materials, and at least one of the luminescent materials is a metal complex having a tridentate or higher polydentate chain ligand (i.e. a ligand having three or more coordination sites).

<2> The organic electroluminescent device described in <1>, wherein a metal ion in the metal complex is at least one ion selected from the group consisting of platinum, iridium, rhenium, palladium, rhodium, ruthenium, and copper ions.

<3> The organic electroluminescent device described in <1> or <2>, wherein the metal complex is a metal complex that emits phosphorescence.

<4> The organic electroluminescent device described in any one of <1> to <3>, wherein at least two of the luminescent materials are metal complexes each having a tridentate or higher polydentate ligand.

<5> The organic electroluminescent device described in any one of <1> to <4>, wherein the metal complex is a compound represented by formula (1): 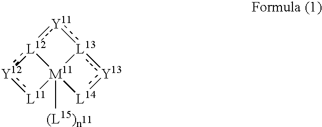
wherein, M¹¹ represents a metal ion; L¹¹, L¹², L¹³, L¹⁴, and L¹⁵ each represent a ligand to coordinate to M¹¹; L¹¹ and L¹⁴ do not combine together via an atomic group, to form a cyclic ligand; L¹⁵ does not bond to L¹¹ and L¹⁴, to form a cyclic ligand; Y¹¹, Y¹², and Y¹³ each represent a linking group, a single bond, or a double bond; a bond between L¹¹ and Y¹², a bond between Y¹² and L¹², a bond between L¹² and Y¹¹, a bond between Y¹¹ and L¹³, a bond between L¹³ and Y¹³, and a bond between Y¹³ and L¹⁴ each represent a single bond, or a double bond; and n¹¹ represents 0 to 4.

<6> The organic electroluminescent device described in any one of <1> to <5>, wherein the metal complex is a compound represented by formula (2): 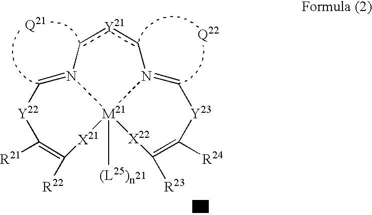
wherein, M²¹ represents a metal ion; Y²¹ represents a linking group, a single bond, or a double bond; Y²² and Y²³ each represent a single bond or a linking group; Q²¹ and Q²² each represent an atomic group necessary to form a nitrogen-containing heterocycle; a bond between Y²¹ and the ring formed with Q²¹, and a bond between Y²¹ and the ring formed with Q²² each represent a single bond, or a double bond; X²¹ and X²² each represent an oxygen atom, a sulfur atom, or a substituted or unsubstituted nitrogen atom; R²¹, R²², R²³, and R²⁴ each represent a hydrogen atom, or a substituent; R²¹ and R²², and R²³ and R²⁴, respectively, may bond to each other to form a ring; L²⁵ represents a ligand to coordinate to M²¹; and n²¹ represents an integer of 0 to 4.

<7> The organic electroluminescent device described in <6>, wherein the ring formed with Q²¹ and the ring formed with Q²² each are a pyridine ring, and Y²¹ represents a linking group composed of at least one atom.

<8> The organic electroluminescent device described in <6>, wherein the ring formed with Q²¹ and the ring formed with Q²² each are a pyridine ring, and Y²¹ represents a single bond or a double bond, and X²¹ and X²² each represent a sulfur atom or a substituted or unsubstituted nitrogen atom.

<9> The organic electroluminescent device described in <6>, wherein the ring formed with Q²¹ and the ring formed with Q²² each are a 5-membered nitrogen-containing heterocycle.

<10> The organic electroluminescent device described in <6>, wherein the ring formed with Q²¹ and the ring formed with Q²² each are a 6-membered nitrogen-containing heterocycle having at least two nitrogen atoms.

<11> The organic electroluminescent device described in any one of <1> to <5>, wherein the metal complex is a compound represented by formula (9): 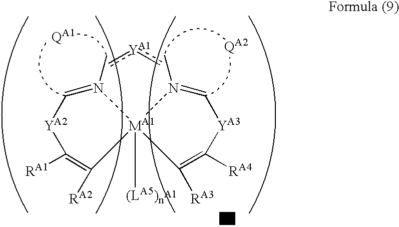
wherein, M^{A1} represents a metal ion; Q^{A1} and Q^{A2} each represent an atomic group necessary to form a nitrogen-containing heterocycle; R^{A1}, R^{A2}, R^{A3}, and R^{A4} each represent a hydrogen atom, or a substituent; R^{A1} and R^{A2}, and R^{A3} and R^{A4}, respectively, may bond to each other to form a ring; Y^{A2} and Y^{A3} each represent a linking group or a single bond; Y^{A1} represents a linking group, a single bond, or a double bond, for linking two bidentate ligands in parentheses together; L^{A5} represents a ligand to coordinate to M^{A1}; and n^{A1} represents an integer of 0 to 4.

<12> The organic electroluminescent device described in <11>, wherein the metal complex is a compound represented by formula (11): 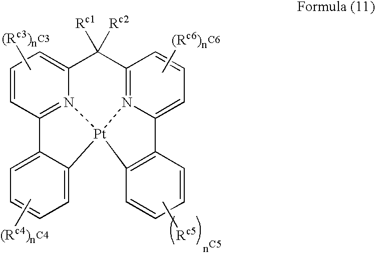
wherein, R^{C1} and R^{C2} each represent a hydrogen atom or a substituent; R^{C3}, R^{C4}, R^{C5}, and R^{C6} each represent a substituent; n^{C3} and n^{C6} each represent an integer of 0 to 3; n^{C4} and n^{C5} each represent an integer of 0 to 4; when a plurality of R^{C3}, R^{C4}, R^{C5}, or R^{C6} exists, the respective R^{C3}s, R^{C4}s, R^{C5}s, or R^{C6}s may be the same or different from each other, and, respectively, the R^{C3}s, R^{C4}s, R^{C5}s, or R^{C6}s may bond to each other to form a ring.

<13> The organic electroluminescent device described in any one of <1> to <5>, wherein the metal complex is a compound represented by formula (10): 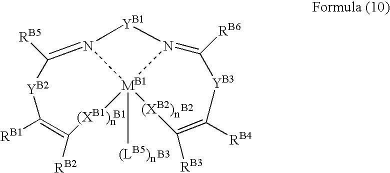
wherein, M^{B1} represents a metal ion; Y^{B1} represents a linking group; Y^{B2} and y^{B3} each represent a linking group or a single bond; X^{B1} and X^{B2} each represent an oxygen atom, a sulfur atom, or a substituted or unsubstituted nitrogen atom; n^{B1} and n^{B2} each represent an integer of 0 to 1; R^{B1}, R², R^{B3}, R^{B4}, R^{B5}, and R^{B6} each represent a hydrogen atom, or a substituent; R^{B1} and R^{B2}, and R^{B3} and R^{B4}, respectively, may bond to each other to form a ring; LBS represents a ligand to coordinate to M^{B1}; n^{B3} represents an integer of 0 to 4; and Y^{B1} does not link to R^{B5} or R^{B6}.

<14> The organic electroluminescent device described in <13>, wherein the metal complex is a compound represented by formula (12): 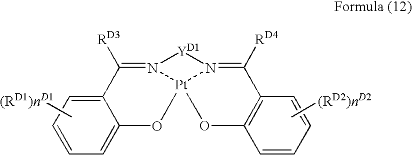
wherein, R^{D3} and R^{D4} each represent a hydrogen atom or a substituent; R^{D1} and R^{D2} each represent a substituent; n^{D1} and n^{D2} each represent an integer of 0 to 4; when a plurality of R^{D1} or R^{D2} exists, the respective R^{D1}s or R^{D2}s may be the same or different from each other, and, respectively, the R^{D1}s or R^{D2}S may bond to each other to form a ring; and Y^{D1} represents a vinyl group that substitutes with 1- and 2-positions, a phenylene group, a pyridine ring, a pyrazine ring, a pyrimidine ring, or a methylene group having 1 to 8 carbon atoms.

<15> The organic electroluminescent device described in any one of <1> to <5>, wherein the metal complex is a compound represented by formula (8): 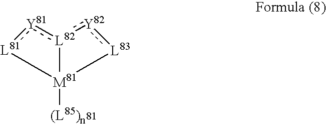
wherein, M⁸¹ represents a metal ion; L⁸¹, L⁸², L⁸³, and L⁸⁵ each represent a ligand to coordinate to M⁸¹; L⁸¹ and L⁸³ do not combine together via an atomic group, to form a cyclic ligand or a tetradentate or higher-polydentate ligand; L⁸⁵ does not directly bond to L⁸¹ or L⁵³, but bonds to via the metal; Y⁸¹ and Y⁸² each represent a linking group, a single bond, or a double bond; and n⁸¹ represents an integer of 0 to 3.

<16> The organic electroluminescent device described in <15>, wherein L⁸¹, L⁸², and L⁸³ each represent an aromatic carbocycle or heterocycle to coordinate to M⁸¹ via a carbon atom, or a nitrogen-containing heterocycle to coordinate to M⁸¹ via a nitrogen atom, and at least one of L⁸¹, L⁸², and L⁸³ is the nitrogen-containing heterocycle.

<17> The organic electroluminescent device described in any one of <1> to <5>, wherein the metal complex is a metal complex represented by formula (X1): 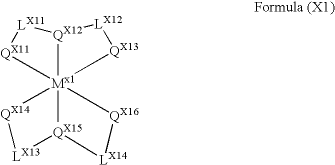
wherein, M^{X1} represents a metal ion; Q^{X11}, Q^{X12}, Q^{X13}, Q^{X14}, Q^{X15}, and Q^{X16} each represent an atom to coordinate to M^{X1} or an atomic group having an atom to coordinate to M^{X1}; L^{X11}, L^{X12}, L^{X13}, and L^{X14} each represent a single bond, a double bond, or a linking group; an atomic group consisted of Q^{X11}-L^{X11}-Q^{X12}-L^{X12}-Q^{X13} and an atomic group consisted of Q^{X14}-L^{X13}-Q^{X15}-L^{X14}-Q^{X16} each represent a tridentate ligand; and a bond between M^{X1} and Q^{X11}, a bond between M^{X1} and Q^{X12} a bond between M^{X1} and Q^{X13}, a bond between M^{X1} and Q^{X14}, a bond between M^{X1} and Q^{X15}, and a bond between M^{X1} and Q^{X16} each are a coordinate bond or a covalent bond.

<18> The organic electroluminescent device described in <17>, wherein the metal complex represented by formula (X1) is a metal complex represented by formula (X2): 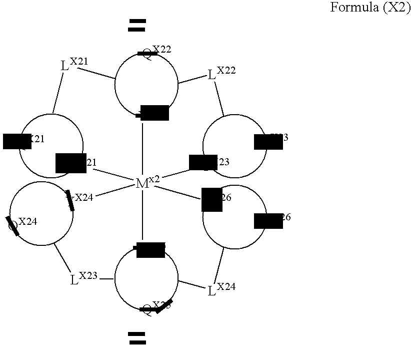
wherein, M^{X2} represents a metal ion; Y^{X21}, Y^{X12}, Y^{X23}, Y^{X24}, Y^{X25}, and Y^{X26} each represent an atom to coordinate to M^{X2}; each of Q^{X21}, Q^{X22}, Q^{X23}, Q^{X24}, Q^{X25}, and Q^{X26} respectively represents an atomic group necessary to form an aromatic ring or aromatic heterocycle together with each of Y^{X21}, Y^{X22}, Y^{X23}, Y^{X24}, Y^{X25}, and Y^{X26}, respectively; L^{X21}, L^{X22}, L^{X23}, and L^{X24} each represent a single bond, a double bond, or a linking group; and a bond between M^{X2} and Y^{X21}, a bond between M^{X2} and Y^{X22}, a bond between M^{X2} and Y^{X23}, a bond between M^{X2} and Y^{X24}, a bond between M^{X2} and Y^{X25}, and a bond between M^{X2} and Y^{X26} each are a coordinate bond or a covalent bond.

<19> The organic electroluminescent device described in <17>, wherein the metal complex represented by formula (X1) is a metal complex represented by formula (X3): 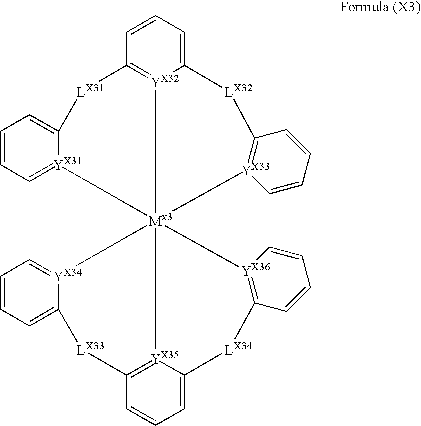
wherein, M^{X3} represents a metal ion; Y^{X31}, Y^{X32}, Y^{X33}, Y^{X34}, Y^{X35}, and Y^{X36} each represent a carbon atom, a nitrogen atom, or a phosphorus atom; L^{X31}, L^{X32}, L^{X33}, and L^{X34} each represent a single bond, a double bond, or a linking group; and a bond between M^{X3} and Y^{X31}, a bond between M^{X3} and Y^{X32}, a bond between M^{X3} and Y^{X33}, a bond between M^{X3} and Y^{X34}, a bond between M^{X3} and Y^{X35}, and a bond between M^{X3} and Y^{X36} each are a coordinate bond or a covalent bond.

<20> The organic electroluminescent device described in any one of claims <1> to <19>, wherein the host material of the luminescent layer consists of two or more kinds of compounds.

The term “chain ligand” used in this specification means ligands except cyclic ligands (e.g. porphyrin and phthalocyanine). If formula (8) is taken as an example, said term means such a ligand in which L⁸¹ and L⁸³ do not directly connect but connect via Y⁸¹, L⁸², Y⁸², and M⁸¹. Even in the case where L⁸¹, Y⁸¹, L⁸², Y82, or L⁸³ contains a ring structure (e.g. benzene, pyridine, and quinoline), the ligand is referred to as a chain ligand, as long as L⁸¹ and L⁸³ do not directly combine but combine via Y⁸¹, L⁸², Y⁸², and M⁸¹. An additional atomic group may exist between L⁸¹ and Y⁸¹, or Y⁸¹ and L⁸², or L⁸² and Y⁸², or Y⁸² and L⁸³, to form a ring.

Organic Electroluminescent Device

The organic electroluminescent device of the present invention (hereinafter referred to as “device of the present invention”. “luminescent device”, or “light-emitting device” occasionally) is described below in detail.

The device of the present invention is an organic electroluminescent device having at least one organic-compound layer (such an organic-compound layer may be a layer consisted of an organic compound only or an organic layer containing an inorganic compound) between a pair of electrodes, with one of the organic-compound layer(s) being an organic luminescent layer; and the organic luminescent layer comprises a host material and two or more luminescent materials; and at least one of the luminescent material is a metal complex having a tridentate or higher polydentate chain ligand.

As the metal complex having a tridentate or higher polydentate chain ligand for use in the present invention (hereinafter sometimes referred to as a metal complex for use in the present invention), metal complexes having a tridentate to octadentate chain ligand are preferable, metal complexes having a tetradentate to octadentate chain ligand are more preferable, metal complexes having a tetradentate to hexadentate chain ligand are furthermore preferable, and metal complexes having a tetradentate chain ligand are most preferable.

According to the present invention, it is sufficient that at least one luminescent material of the at least two luminescent materials has a tridentate or higher polydentate ligand, but two or more luminescent materials may each have a tridentate or higher polydentate ligand.

The chain ligand for use in the present invention preferably contains at least one nitrogen-containing heterocycle (e.g., pyridine ring, quinoline ring, pyrrole ring) to coordinate to the central metal {if formula (1) is taken as an example, said metal is represented by M¹¹} via a nitrogen atom.

A compound to be used as a luminescent material in the present invention may be a compound to emit fluorescence (a fluorescent compound) or a compound to emit phosphorescence (a phosphorescent compound), with a phosphorescent compound being preferred. (More preferred are compounds to emit phosphorescence preferably at not less than −30° C., more preferably at not less than −10° C., furthermore preferably at not less than 0° C., and particularly preferably at not less than 10° C.) When a compound to emit phosphorescence is used, the compound may emit fluorescence at the same time. In this case, preferred is a compound whose intensity of phosphorescence at 20° C. is not less than 2 times the intensity of fluorescence, more preferably not less than 10 times, and furthermore preferably not less than 100 times.

The luminescent material used in the present invention may be preferably a material the emission quantum yield (phosphorescence or fluorescence) at a temperature of 20° C. of which is 10% or above, more preferably 15% or above, and most preferably 20% or above.

A density of the luminescent material (preferably metal complex) that can be used in the present invention is preferably in the range of from 0.1 to 20% by mass, more preferably in the range of from 0.3 to 15% by mass, and further more preferably in the range of from 0.5 to 10% by mass, based on the mass of the luminescent layer.

The content ratio of the at least two luminescent materials added to the luminescent layer is not specifically limited, but the ratio {luminescent material from which spectrum emission originates}/{other luminescent material} is preferably 100/1 to 1/10 by mass, more preferably 20/1 to 1/5, and most preferably 5/1 to 1/2.

In this connection, spectrum origin for emission is determined in the manner as described below:

Among the peaks (maximum values) observed for the electronic excitation emission spectrum of an organic electroluminescent device, peaks each having an intensity at least 1/10 times the largest maximum peak value are chosen. Separately, each of the compounds constituting the electroluminescent device is formed into a single-layered film, and the light excitation emission spectrum of each of the film is obtained. The wavelengths of the peaks chosen and that of the peak having the largest maximum value of the electroluminescent device are compared with the peak wavelengths of the spectrums observed for respective single-layered films. The origin of emission for a peak in the spectrum of the electroluminescent device is the compound that showed most similar peak wavelength to the peak.

A preferable embodiment of the metal complex for use in the present invention having a tetradentate or higher polydentate ligand is represented by formula (1). Preferable embodiments of the metal complex represented by formula (1) are those represented by formula (2), (5), (9), or (10).

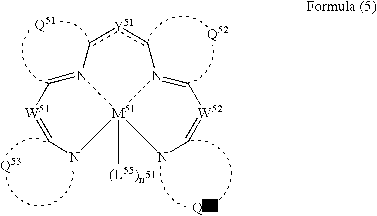

A preferable embodiment of the metal complex represented by formula (2) is one represented by formula (3).

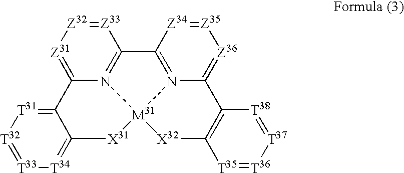

Preferable embodiments of the metal complex represented by formula (9) are those represented by formula (6) or (7), and a preferable embodiment of the metal complex represented by formula (7) is one represented by formula (11).

A preferable embodiment of the metal complex represented by formula (10) is one represented by formula (12).

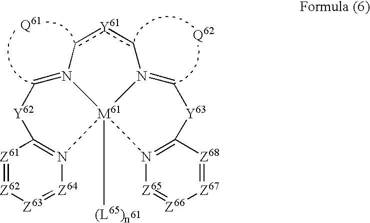

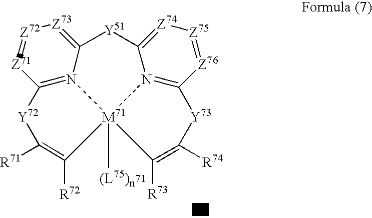

In the following, the compound represented by formula (1) will be explained.

M¹¹ represents a metal ion. The metal ion is not particularly restricted, but divalent or trivalent metal ions are preferable. As the divalent or trivalent metal ions, platinum, iridium, rhenium, palladium, rhodium, ruthenium, copper, europium, gadolinium, and terbium ions are preferable. Of these ions, platinum, iridium, rhenium, palladium, rhodium, ruthenium, copper ions are more preferable; platinum and iridium ions are furthermore preferable; and a platinum ion is particularly preferable.

L¹¹, L¹², L¹³, and L¹⁴ each represent a ligand to coordinate to M¹¹. As the atom that is contained in L¹¹, L¹², L¹³, or L¹⁴ and coordinates to M¹¹, nitrogen, oxygen, sulfur, and carbon atoms are preferable, and nitrogen, oxygen, and carbon atoms are more preferable.

The bond to be formed between M¹¹ and L¹¹, between M¹¹ and L¹², between M¹¹ and L¹³, or between M¹¹ and L¹⁴ may be a covalent bond, an ion bond, or a coordination bond. The ligand that is composed of L¹¹, Y¹², L¹², Y¹¹, L¹³, Y¹³, and L¹⁴ is preferably an anionic ligand (i.e., a ligand that bonds to the metal, with at least one anion of the ligand). The number of anions in the anionic ligand is preferably 1 to 3, more preferably 1 or 2, and furthermore preferably 2.

L¹¹, L¹², L¹³, or L¹⁴ to coordinate to M¹¹ via a carbon atom, is not particularly restricted. Examples of these ligands include imino ligands, aromatic carbocyclic ligands (for example, benzene, naphthalene, anthracene, phenanthracene ligands), heterocyclic ligands {for example, thiophene, pyridine, pyrazine, pyrimidine, thiazole, oxazole, pyrrole, imidazole, pyrazole ligands, condensed rings containing these rings (e.g., quinoline, benzothiazole ligands), and tautomers of these rings}. These ligands may be further substituted with a substituent.

L¹¹, L¹², L¹³, or L¹⁴ to coordinate to M¹¹ via a nitrogen atom is not particularly restricted. Examples of these ligands include nitrogen-containing heterocyclic ligands {for example, pyridine, pyrazine, pyrimidine, pyridazine, triazine, thiazole, oxazole, pyrrole, imidazole, pyrazole, triazole, oxadiazole, and thiadiazole ligands, condensed rings containing any of these ligands (e.g., quinoline, benzoxazole, benzimidazole ligands), and tautomers of these ligands (in the present invention, the tautomers are defined as it means that the following examples are also embraced in the tautomer in addition to ordinary tautomers; for example, the 5-membered heterocyclic ligand of Compound (24), the terminal 5-membered heterocyclic ligand of Compound (64), and a 5-membered heterocyclic ligand of Compound (145) are defined as pyrrole tautomers)}, and amino ligands {for example, alkylamino ligands (those having carbon atoms preferably in the range of 2 to 30, more preferably in the range of 2 to 20, and particularly preferably in the range of 2 to 10; for example, methylamino), arylamino ligands (for example, phenylamino), acylamino ligands (those having carbon atoms preferably in the range of 2 to 30, more preferably in the range of 2 to 20, and particularly preferably in the range of 2 to 10; for example, acetylamino, benzoylamino), alkoxycarbonylamino ligands (those having carbon atoms preferably in the range of 2 to 30, more preferably in the range of 2 to 20, and particularly preferably in the range of 2 to 12; for example, methoxycarbonylamino), aryloxycarbonylamino ligands (those having carbon atoms preferably in the range of 7 to 30, more preferably in the range of 7 to 20, and particularly preferably in the range of 7 to 12; for example, phenyloxycarbonylamino), sulfonylamino ligands (those having carbon atoms preferably in the range of 1 to 30, more preferably in the range of 1 to 20, and particularly preferably in the range of 1 to 12; for example, methane sulfonylamino, benzene sulfonylamino), and imino ligands}. These ligands may be further substituted with a substituent.

L¹¹, L¹², L¹³, or L¹⁴ to coordinate to M¹¹ via an oxygen atom is not particularly restricted. Examples of these ligands include alkoxy ligands (those having carbon atoms preferably in the range of 1 to 30, more preferably in the range of 1 to 20, and particularly preferably in the range of 1 to 10; for example, methoxy, ethoxy, butoxy, 2-ethylhexyloxy), aryloxy ligands (those having carbon atoms preferably in the range of 6 to 30, more preferably in the range of 6 to 20, and particularly preferably in the range of 6 to 12; for example, phenyloxy, 1-naphthyloxy, 2-naphthyloxy), heterocyclic oxy ligands (those having carbon atoms preferably in the range of 1 to 30, more preferably in the range of 1 to 20, and particularly preferably in the range of 1 to 12; for example, pyridyloxy, pyrazyloxy, pyrimidyloxy, quinolyloxy), acyloxy ligands (those having carbon atoms preferably in the range of 2 to 30, more preferably in the range of 2 to 20, and particularly preferably in the range of 2 to 10; for example, acetoxy, benzoyloxy), silyloxy ligands (those having carbon atoms preferably in the range of 3 to 40, more preferably in the range of 3 to 30, and particularly preferably in the range of 3 to 24; for example, trimethyl silyloxy, triphenyl silyloxy), carbonyl ligands (for example, ketone ligands, ester ligands, amide ligands), and ether ligands (for example, dialkylether ligands, diarylether ligands, furyl ligands). These ligands may be further substituted with a substituent.

L¹¹, L¹², L¹³, or L¹⁴ to coordinate to M¹¹ via a sulfur atom is not particularly restricted. Examples of these ligands include alkylthio ligands (those having carbon atoms preferably in the range of 1 to 30, more preferably in the range of 1 to 20, and particularly preferably in the range of 1 to 12; for example, methylthio, ethylthio), arylthio ligands (those having carbon atoms preferably in the range of 6 to 30, more preferably in the range of 6 to 20, and particularly preferably in the range of 6 to 12; for example, phenylthio), heterocyclic thio ligands (those having carbon atoms preferably in the range of 1 to 30, more preferably in the range of 1 to 20, and particularly preferably in the range of 1 to 12; for example, pyridylthio, 2-benzimidazolylthio, 2-benzoxazolylthio, 2-benzthiazolylthio), thiocarbonyl ligands (for example, thioketone ligands, thioester ligands), and thioether ligands (for example, dialkylthioether ligands, diarylthioether ligands, thiofuryl ligands). Further, these ligands may be further substituted with a substituent.

Preferably, L¹¹ and L¹⁴ each are an aromatic carbocyclic ligand, an alkyloxy ligand, an aryloxy ligand, an ether ligand, an alkylthio ligand, an arylthio ligand, an alkylamino ligand, an arylamino ligand, an acylamino ligand, and a nitrogen-containing heterocyclic ligand (for example, pyridine, pyrazine, pyrimidine, pyridazine, triazine, thiazole, oxazole, pyrrole, imidazole, pyrazole, triazole, oxadiazole, and thiadiazole ligands; a condensed ligand containing any of these ligands (e.g., quinoline, benzoxazole, benzimidazole ligands); and a tautomer of any of these ligands). Of these ligands, an aromatic carbocyclic ligand, an aryloxy ligand, an arylthio ligand, an arylamino ligand, a pyridine ligand, a pyrazine ligand, an imidazole ligand, a condensed ligand containing any of these ligands (e.g., quinoline, quinoxaline, benzimidazole ligands); and a tautomer of any of these ligands are more preferable. An aromatic carbocyclic ligand, an aryloxy ligand, an arylthio ligand, and an arylamino ligand are furthermore preferable with the aromatic carbocyclic ligand and aryloxy ligand being most preferable.

L¹² and L¹³ each are preferably a ligand to form a coordinate bond with M¹¹. As the ligand to form a coordinate bond with M¹¹, a pyridine ring, a pyrazine ring, a pyrimidine ring, a triazine ring, a thiazole ring, an oxazole ring, a pyrrole ring, a triazole ring, a condensed ring containing any of these rings (e.g., quinoline, benzoxazole, benzimidazole, and indolenine rings); and a tautomer of any of these rings are preferable. Of these, a pyridine ring, a pyrazine ring, a pyrimidine ring, a pyrrole ring, a condensed ring containing any of these rings (e.g., quinoline, benzpyrrole rings); and a tautomer of any of these rings are preferable. A pyridine ring, a pyrazine ring, a pyrimidine ring, and a condensed ring containing any of these rings (e.g., a quinoline ring) are more preferable. A pyridine ring and a condensed ring containing a pyridine ring (e.g., a quinoline ring) are particularly preferable.

L¹⁵ represents a ligand to coordinate to M¹¹. L¹⁵ is preferably a monodentate to tetradentate ligand, more preferably an anionic, monodentate to tetradentate ligand. The anionic, monodentate to tetradentate ligand is not particularly restricted, but it is preferably a halogen ligand, a 1,3-diketone ligand (e.g., acetylacetone ligand), a monoanionic bidentate ligand containing a pyridine ligand (e.g., picolinic acid, 2-(2-hydroxyphenyl)-pyridine ligands), and a tetradentate ligand formed with L¹¹, Y¹², L¹², Y¹¹, L¹³, Y¹³, and L¹⁴; more preferably a 1,3-diketone ligand (e.g., acetylacetone ligand), a monoanionic bidentate ligand containing a pyridine ligand (e.g., picolinic acid, 2-(2-hydroxyphenyl)-pyridine ligands), and a tetradentate ligand formed with L¹¹, Y¹², L¹², Y¹¹, L¹³, Y¹³, and L¹⁴; furthermore preferably a 1,3-diketone ligand (e.g., acetylacetone ligand), and a monoanionic bidentate ligand containing a pyridine ligand (e.g., picolinic acid, 2-(2-hydroxyphenyl)-pyridine ligands); and particularly preferably a 1,3-diketone ligand (e.g., acetylacetone ligand). The coordination numbers and ligand numbers do not exceed the coordination number of the metal. L¹⁵ does not bond to both L¹¹ and L¹⁴, to form a cyclic ligand together with them.

Y¹¹, Y¹², and Y¹³ each represent a linking group, a single bond, or a double bond. The linking group is not particularly restricted. Examples of the linking group include a carbonyl linking group (—CO—), a thiocarbonyl linking group (—CS—), an alkylene group, an alkenylene group, an arylene group, a heteroarylene group, an oxygen atom-linking group (—O—), a nitrogen atom-linking group (—N—), a silicon atom-linking group (—Si—), and a linking group comprising a combination of these groups. A bond between L¹¹ and Y¹², a bond between Y¹² and L¹², a bond between L¹² and Y¹¹, a bond between Y¹¹and L¹³, a bond between L¹³ and Y¹³, and a bond between Y¹³ and L¹⁴ each represent a single bond, or a double bond.

Y¹¹, Y¹², and Y¹³ each are preferably a single bond, a double bond, a carbonyl linking group, an alkylene linking group, or an alkenylene group. Y¹¹ is more preferably a single bond or an alkylene group, and furthermore preferably an alkylene group, Y¹² and Y¹³ each are more preferably a single bond or an alkenylene group, and furthermore preferably a single bond.

The number of members of the ring formed by Y¹², L¹¹, L¹², and M¹¹, the ring formed by Y¹¹, L¹², L¹³, and M¹¹, and the ring formed by Y¹³, L¹³, L¹⁴, and M¹¹ each are preferably in the range of from 4 to 10, more preferably in the range of from 5 to 7, and furthermore preferably 5 or 6.

n¹¹ represents 0 to 4. When M¹¹ is a metal that has a coordination number of 4, n¹¹ is 0. When M¹¹ is a metal that has a coordination numbers of 6, n¹¹ is preferably 1 or 2, more preferably 1. When M¹¹ is a metal that has a coordination number of 6 and n¹¹ is 1, L¹⁵ represents a bidentate ligand. When M¹¹ is a metal that has a coordination number of 6 and n¹¹ is 2, L¹⁵ represents a monodentate ligand. When M¹¹ is a metal that has a coordination number of 8, n¹¹ is preferably 1 to 4, more preferably 1 or 2, and furthermore preferably. 1. When M¹¹ is a metal that has a coordination number of8 and n¹¹ is 1, L¹⁵ represents a tetradentate ligand, whereas when M¹¹ is a metal that has a coordination number of 8 and n¹¹ is 2, L¹⁵ represents a bidentate ligand. When n¹¹ is 2 or more, plural L¹⁵s may be the same or different from each other.

Next, the compound represented by formula (2) will be explained.

M²¹ has the same meaning as that of the aforementioned M¹¹, with the same preferable range.

Q²¹ and Q²² each represent a group for forming a nitrogen-containing heterocycle (a ring containing a nitrogen atom that coordinates to M²¹). The nitrogen-containing heterocycle formed by Q²¹ or Q²² is not particularly limited, and examples include a pyridine ring, a pyrazine ring, a pyrimidine ring, a triazine ring, a thiazole ring, an oxazole ring, a pyrrole ring, a triazole ring, a condensed ring containing any of these rings (e.g., quinoline, benzoxazole, benzimidazole, and indolenine rings); and a tautomer of these rings.

The nitrogen-containing heterocycle formed by Q²¹ or Q²² is preferably a pyridine ring, a pyrazine ring, a pyrimidine ring, a pyridazine ring, a triazine ring, a pyrazole ring, an imidazole ring, an oxazole ring, a pyrrole ring, a benzazole ring, a condensed ring containing any of these rings (e.g., quinoline, benzoxazole, and benzimidazole rings); and a tautomer of any of these rings. The nitrogen-containing heterocycle formed by Q²¹ or Q²² is more preferably a pyridine ring, a pyrazine ring, a pyrimidine ring, an imidazole ring, a pyrrole ring, a condensed ring containing any of these rings (e.g., quinoline ring); and a tautomer of any of these rings. The nitrogen-containing heterocycle formed by Q²¹ or Q²² is further preferably a pyridine ring, a condensed ring containing a pyridine ring (e.g., quinoline ring); and particularly preferably a pyridine ring. Further, these rings may be further substituted with a substituent.

X²¹ and X²² each are preferably an oxygen atom, a sulfur atom, or a substituted or unsubstituted nitrogen atom. They each are more preferably an oxygen atom, a sulfur atom, or a substituted nitrogen atom; further preferably an oxygen atom or a sulfur atom; and particularly preferably an oxygen atom.

Y²¹ has the same meaning as that of the aforementioned Y¹¹, with the same preferable range.

Y²² and Y²³ each represent a single bond or a linking group, and preferably a single bond. The linking group is not particularly restricted. Examples of the linking group include a carbonyl linking group, a thiocarbonyl linking group, an alkylene group, an alkenylene group, an arylene group, a hetero arylene group, an oxygen-atom linking group, a nitrogen-atom linking group, and a linking group formed by a combination of any of these linking groups.

As the aforementioned linking group, a carbonyl linking group, an alkylene linking group, and an alkenylene linking group are preferable. Of these, a carbonyl linking group and an alkenylene linking group are more preferable with the carbonyl linking group being furthermore preferable.

R²¹, R²², R²³, and R²⁴ each represent a hydrogen atom, or a substituent. The substituent is not particularly limited. Examples of the substituent include an alkyl group (an alkyl group having preferably 1 to 30 carbon atoms, more preferably 1 to 20 carbon atoms, particularly preferably 1 to 10 carbon atoms, e.g. methyl, ethyl, iso-propyl, tert-butyl, n-octyl, n-decyl, n-hexadecyl, cyclopropyl, cyclopentyl, and cyclohexyl), an alkenyl group (an alkenyl group having preferably 2 to 30 carbon atoms, more preferably 2 to 20 carbon atoms, particularly preferably 2 to 10 carbon atoms, e.g. vinyl, allyl, 2-butenyl, and 3-pentenyl), an alkynyl group (an alkynyl group having preferably 2 to 30 carbon atoms, more preferably 2 to 20 carbon atoms, particularly preferably 2 to 10 carbon atoms, e.g. propargyl, and 3-pentynyl), an aryl group (an aryl group having preferably 6 to 30 carbon atoms, more preferably 6 to 20 carbon atoms, particularly preferably 6 to 12 carbon atoms, e.g. phenyl, p-methylphenyl, naphthyl, and anthranyl), an amino group (an amino group having preferably 0 to 30 carbon atoms, more preferably 0 to 20 carbon atoms, particularly preferably 0 to 10 carbon atoms, e.g. amino, methylamino, dimethylamino, diethylamino, dibenzylamino, diphenylamino, and ditolylamino), an alkoxy group (an alkoxy group having preferably 1 to 30 carbon atoms, more preferably 1 to 20 carbon atoms, particularly preferably 1 to 10 carbon atoms, e.g. methoxy, ethoxy, butoxy, and 2-ethylhexyloxy), an aryloxy group (an aryloxy group having preferably 6 to 30 carbon atoms, more preferably 6 to 20 carbon atoms, particularly preferably 6 to 12 carbon atoms, e.g. phenyloxy, 1-naphthyloxy, and 2-naphthyloxy), a heterocyclic oxy group (a heterocyclic oxy group having preferably 1 to 30 carbon atoms, more preferably 1 to 20 carbon atoms, particularly preferably 1 to 12 carbon atoms, e.g. pyridyloxy, pyrazyloxy, pyrimidyloxy, and quinolyloxy), an acyl group (an acyl group having preferably 1 to 30 carbon atoms, more preferably 1 to 20 carbon atoms, particularly preferably 1 to 12 carbon atoms, e.g. acetyl, benzoyl, formyl, and pivaloyl), an alkoxycarbonyl group (an alkoxycarbonyl group having preferably 2 to 30 carbon atoms, more preferably 2 to 20 carbon atoms, particularly preferably 2 to 12 carbon atoms, e.g. methoxycarbonyl, and ethoxycarbonyl), an aryloxycarbonyl group (an aryloxycarbonyl group having preferably 7 to 30 carbon atoms, more preferably 7 to 20 carbon atoms, particularly preferably 7 to 12 carbon atoms, e.g. phenyloxycarbonyl), an acyloxy group (an acyloxy group having preferably 2 to 30 carbon atoms, more preferably 2 to 20 carbon atoms, particularly preferably 2 to 10 carbon atoms, e.g. acetoxy, and benzoyloxy), an acylamino group (an acylamino group having preferably 2 to 30 carbon atoms, more preferably 2 to 20 carbon atoms, particularly preferably 2 to 10 carbon atoms, e.g. acetylamino, and benzoylamino), an alkoxycarbonylamino group (an alkoxycarbonylamino group having preferably 2 to 30 carbon atoms, more preferably 2 to 20 carbon atoms, particularly preferably 2 to 12 carbon atoms, e.g. methoxycarbonylamino), an aryloxycarbonylamino group (an aryloxycarbonylamino group having preferably 7 to 30 carbon atoms, more preferably 7 to 20 carbon atoms, particularly preferably 7 to 12 carbon atoms, e.g. phenyloxycarbonylamino), a sulfonylamino group (a sulfonylamino group having preferably 1 to 30 carbon atoms, more preferably 1 to 20 carbon atoms, particularly preferably 1 to 12 carbon atoms, e.g. methanesulfonylamino, and benzenesulfonylamino), a sulfamoyl group (a sulfamoyl group having preferably 0 to 30 carbon atoms, more preferably 0 to 20 carbon atoms, particularly preferably 0 to 12 carbon atoms, e.g. sulfamoyl, methylsulfamoyl, dimethylsulfamoyl, and phenylsulfamoyl), a carbamoyl group (a carbamoyl group having preferably 1 to 30 carbon atoms, more preferably 1 to 20 carbon atoms, particularly preferably 1 to 12 carbon atoms, e.g. carbamoyl, methylcarbamoyl, diethylcarbamoyl, and phenylcarbamoyl), an alkylthio group (an alkylthio group having preferably 1 to 30 carbon atoms, more preferably 1 to 20 carbon atoms, particularly preferably 1 to 12 carbon atoms, e.g. methylthio, and ethylthio), an arylthio group (an arylthio group having preferably 6 to 30 carbon atoms, more preferably 6 to 20 carbon atoms, particularly preferably 6 to 12 carbon atoms, e.g. phenylthio), a heterocyclic thio group (a heterocyclic thio group having preferably 1 to 30 carbon atoms, more preferably 1 to 20 carbon atoms, particularly preferably 1 to 12 carbon atoms, e.g. pyridylthio, 2-benzimidazolylthio, 2-benzoxazolylthio, and 2-benzothiazolylthio), a sulfonyl group (a sulfonyl group having preferably 1 to 30 carbon atoms, more preferably 1 to 20 carbon atoms, particularly preferably 1 to 12 carbon atoms, e.g. mesyl, and tosyl), a sulfinyl group (a sulfinyl group having preferably 1 to 30 carbon atoms, more preferably 1 to 20 carbon atoms, particularly preferably 1 to 12 carbon atoms, e.g. methanesulfinyl, and benzenesulfinyl), a ureido group (a ureido group having preferably 1 to 30 carbon atoms, more preferably 1 to 20 carbon atoms, particularly preferably 1 to 12 carbon atoms, e.g. ureido, methylureido, and phenylureido), a phosphoric acid amido group (a phosphoric acid amido group having preferably 1 to 30 carbon atoms, more preferably 1 to 20 carbon atoms, particularly preferably 1 to 12 carbon atoms, e.g. diethylphosphoric acid amido, and phenylphosphoric acid amido), a hydroxyl group, a mercapto group, a halogen atom (e.g., a fluorine atom, a chlorine atom, a bromine atom, or an iodine atom), a cyano group, a sulfo group, a carboxyl group, a nitro group, a hydroxamic acid group, a sulfino group, a hydrazino group, an imino group, a heterocyclic group (a heterocyclic group having preferably 1 to 30 carbon atoms, more preferably 1 to 12 carbon atoms, with a hetero atom, for example, of a nitrogen atom, an oxygen atom, or a sulfur atom; specific examples include imidazolyl, pyridyl, quinolyl, furyl, thienyl, piperidyl, morpholino, benzoxazolyl, benzimidazolyl, benzothiazolyl, carbazolyl, and azepinyl), a silyl group (a silyl group having preferably 3 to 40 carbon atoms, more preferably 3 to 30 carbon atoms, particularly preferably 3 to 24 carbon atoms, e.g. trimethylsilyl, and triphenylsilyl), and a silyloxy group (a silyloxy group preferably having 3 to 40 carbon atoms, more preferably 3 to 30 carbon atoms, and particularly preferably 3 to 24 carbon atoms, e.g., trimethylsilyloxy, triphenylsilyloxy). These substituents may be further substituted.

Preferably, R²¹, R²², R²³, and R²⁴ each are an alkyl group, an aryl group, a group that forms a condensed ring (for example, benzo-condensed rings, pyridine-condensed rings) by forming a bond between R²¹ and R²², or between R²³ and R²⁴. More preferably, R²¹, R²², R²³, and R²⁴, each are a group that forms a condensed ring (for example, benzo-condensed rings, pyridine-condensed rings) by forming a bond between R²¹ and R²², or between R²³ and R²⁴.

L²⁵ has the same meaning as that of the aforementioned L¹⁵, with the same preferable range.

n²¹ has the same meaning as that of the aforementioned n¹¹, with the same preferable range.

Among metal complexes represented by formula (2), those in which the ring formed by Q²¹ and the ring formed by Q²² each are a pyridine ring and Y²¹ represents a linking group; those in which the ring formed by Q²¹ and the ring formed by Q²² each are a pyridine ring, Y²¹ represents a single bond or a double bond, and X²¹ and X²² each represent a sulfur atom or a substituted or unsubstituted nitrogen atom; and those in which the ring formed by Q²¹ and the ring formed by Q²² each are a nitrogen-containing 5-membered heterocycle or a nitrogen-containing 6-membered heterocycle containing two or more nitrogen atoms, are preferable.

Next, the compound represented by formula (3) will be explained.

M³¹ has the same meaning as that of the aforementioned M¹¹, with the same preferable range.

Z³¹, Z³², Z³³, Z³⁴, Z³⁵, and Z³⁶ each represent a substituted or unsubstituted carbon atom or a nitrogen atom, with the substituted or unsubstituted carbon atom being preferable. Examples of the substituent on the carbon atom include those explained in the aforementioned R²¹. Further, Z³¹ and Z³², Z³² and Z³³, Z³³ and Z³⁴, Z³⁴ and Z³⁵, Z³⁵ and Z³⁶ each may bond to each other via a linking group, to form a condensed ring (for example, a benzo-condensed ring, a pyridine-condensed ring). Alternatively, Z³¹ and T³¹, and Z³⁶ and T³⁸ each may bond to each other via a linking group, to form a condensed ring (for example, a benzo-condensed ring, a pyridine-condensed ring).

As the aforementioned substituent on the carbon atom, an alkyl group, an alkoxy group, an alkylamino group, an aryl group, a group to form a condensed ring (for example, a benzo-condensed ring, a pyridine-condensed ring), and a halogen atom are preferable. Of these, an alkylamino group, an aryl group, and a group to form a condensed ring (for example, a benzo-condensed ring, a pyridine-condensed ring) are more preferable. An aryl group and a group to form a condensed ring (for example, a benzo-condensed ring, a pyridine-condensed ring) are furthermore preferable. A group to form a condensed ring (for example, a benzo-condensed ring, a pyridine-condensed ring) is most preferable.

T³¹, T³², T³³, T³⁴, T³⁵, T³⁶, T³⁷, and T³⁸ each represent a substituted or unsubstituted carbon atom or a nitrogen atom, with the substituted or unsubstituted carbon atom being preferable. Examples of the substituent on the carbon atom include those explained in the aforementioned R²¹. T³¹ and T³², T³² and T³³, T³³ and T³⁴, T³⁵ and T³⁶, T³⁶ and T³⁷, T³⁷ and T³⁸ each may bond to each other via a linking group, to form a condensed ring (for example, a benzo-condensed ring).

As the aforementioned substituent on the carbon atom, an alkyl group, an alkoxy group, an alkylamino group, an aryl group, a group to form a condensed ring (for example, a benzo-condensed ring, a pyridine-condensed ring), and a halogen atom are preferable. Of these, an aryl group, a group to form a condensed ring (for example, a benzo-condensed ring, a pyridine-condensed ring), and a halogen atom are more preferable. An aryl group and a halogen atom are furthermore preferable. An aryl group is most preferable.

X³¹ and X³² have the same meanings as those of the aforementioned X²¹ and X²², respectively, with the same preferable ranges.

Next, the compound represented by formula (5) will be explained.

M⁵¹ has the same meaning as that of the aforementioned M¹¹, with the same preferable range.

Q⁵¹ and Q⁵² have the same meanings as those of the aforementioned Q²¹ and Q²², respectively, with the same preferable ranges.

Q⁵³ and Q⁵⁴ each represent a group to form a nitrogen-containing heterocycle (a ring containing a nitrogen to coordinate to M⁵¹). The nitrogen-containing heterocycle formed by Q⁵³ or Q⁵⁴ is not particularly restricted, but preferably a tautomer of pyrrole derivatives, a tautomer of imidazole derivatives (for example, a 5-membered heterocyclic ligand of Compound (29)), a tautomer of thiazole derivatives (for example, a 5-membered heterocyclic ligand of Compound (30)), and a tautomer of oxazole derivatives (for example, a 5-membered heterocyclic ligand of Compound (31)); more preferably a tautomer of pyrrole derivatives, a tautomer of imidazole derivatives, and a tautomer of thiazole derivatives; furthermore preferably a tautomer of pyrrole derivatives and a tautomer of imidazole derivatives; and especially preferably a tautomer of pyrrole derivatives.

Y⁵¹ has the same meaning as that of the aforementioned Y¹¹, with the same preferable range.

L⁵⁵ has the same meaning as that of the aforementioned L¹⁵, with the same preferable range.

n⁵¹ has the same meaning as that of the aforementioned n¹¹, with the same preferable range.

W⁵¹ and W⁵² each are preferably a substituted or unsubstituted carbon atom or a nitrogen atom. They each are more preferably an unsubstituted carbon atom or a nitrogen atom; further preferably an unsubstituted carbon atom.

Next, the compound represented by formula (9) will be explained.

M^{A1}, Q^{A1}, Q^{A2}, Y^{A1}, y^{A2}, y^{A3}, R^{A1}, R^{A2}, R^{A3}, R^{A4}, L^{A5}, and n^{a1} have the same meanings as those of the aforementioned M²¹, Q²¹, Q²², Y²¹, Y²², Y²³, R²¹, R²², R²³, R²⁴, L²⁵, and n²¹ in formula (2), respectively, with the same preferable ranges.

Next, the compound represented by formula (6) will be explained.

M⁶¹ has the same meaning as that of the aforementioned M¹¹, with the same preferable range.

Q⁶¹ and Q⁶² each represent a group to form a ring. The ring formed by Q⁶¹ or Q⁶² is not particularly restricted. As the ring, there are illustrated, for example, benzene, pyridine, pyridazine, pyrimidine, thiophene, isothiazole, furane, and isoxazole rings and condensed rings thereof. Further, these groups may be further substituted with a substituent.

The ring formed by Q⁶¹ or Q⁶² is preferably a benzene ring, a pyridine ring, a thiophene ring, or a thiazole ring, or a condensed ring thereof; more preferably a benzene ring or a pyridine ring, or a condensed ring thereof; and furthermore preferably a benzene ring and a condensed ring thereof

Y⁶¹ has the same meaning as that of the aforementioned Y¹¹, with the same preferable range. Y⁶² and Y⁶³ each represent a linking group or a single bond. The linking group is not particularly restricted. Examples of the linking group include a carbonyl linking group, a thiocarbonyl linking group, an alkylene group, an alkenylene group, an arylene group, a hetero arylene group, an oxygen-atom linking group, a nitrogen-atom linking group, and a linking group formed by a combination of these linking groups.

Preferably, Y⁶² and Y⁶³ each are a single bond, a carbonyl linking group, an alkylene linking group, or an alkenylene group; more preferably they each are a single bond or an alkenylene group; and further more preferably a single bond.

L⁶⁵ has the same meaning as that of the aforementioned L¹⁵, with the same preferable range.

n⁶¹ has the same meaning as that of the aforementioned n¹¹ with the same preferable range.

Z⁶¹, Z⁶², Z⁶³, Z⁶⁴, Z⁶⁵, Z⁶⁶, Z⁶⁷, and Z⁶⁸ each represent a substituted or unsubstituted carbon atom or a nitrogen atom, with the substituted or unsubstituted carbon atom being preferable. Examples of the substituent on the carbon atom include those explained in the aforementioned R²¹. Further, Z⁶¹ and Z⁶², Z⁶² and Z⁶³, Z⁶³ and Z⁶⁴, Z⁶⁵ and Z⁶⁶, Z⁶⁶ and Z⁶⁷, Z⁶⁷ and Z⁶⁸ each may bond to each other via a linking group, to form a condensed ring (for example, a benzo-condensed ring, a pyridine-condensed ring). The ring formed by Q⁶¹ or Q⁶² may bond to Z⁶¹ or Z⁶⁸ respectively via a linking group, to form a ring.

As the aforementioned substituent on the carbon atom, an alkyl group, an alkoxy group, an alkylamino group, an aryl group, a group to form a condensed ring (for example, a benzo-condensed ring, a pyridine-condensed ring), and a halogen atom are preferable. Of these, an alkylamino group, an aryl group, and a group to form a condensed ring (for example, a benzo-condensed ring, a pyridine-condensed ring) are more preferable. An aryl group and a group to form a condensed ring (for example, a benzo-condensed ring, a pyridine-condensed ring) are furthermore preferable. A group to form a condensed ring (for example, a benzo-condensed ring, a pyridine-condensed ring) is most preferable.

Next, the compound represented by formula (7) will be explained.

M⁷¹ has the same meaning as that of the aforementioned M¹¹, with the same preferable range. Y⁷¹, Y⁷², and Y⁷³ each have the same meanings as those of the aforementioned Y⁶², with the same preferable ranges.

L⁷⁵ has the same meaning as that of the aforementioned L¹⁵, with the same preferable range.

n⁷¹ has the same meaning as that of the aforementioned n¹¹, with the same preferable range.

Z⁷¹, Z⁷², Z⁷³, Z⁷⁴, Z⁷⁵, and Z⁷⁶ each represent a substituted or unsubstituted carbon atom or a nitrogen atom, with the substituted or unsubstituted carbon atom being preferable. Examples of the substituent on the carbon atom include those explained in the aforementioned R²¹. Further, Z⁷¹ and Z⁷², and Z⁷³ and Z⁷⁴ each may bond to each other via a linking group, to form a condensed ring (for example, a benzo-condensed ring, a pyridine-condensed ring).

R⁷¹, R⁷², R⁷³, and R⁷⁴ each have the same meanings as those of the aforementioned R²¹, R²², R²³, and R²⁴ in formula (2), with the same preferable ranges.

The compound represented by formula (11) will be explained.

R^{C1} and R^{C2} each represent a hydrogen atom or a substituent. Examples of the substituent include the alkyl group and aryl group illustrated as the examples of the substituent of R²¹ to R²⁴ in formula (2). The substituents represented by R^{C3}, R^{C4}, R^{C5}, and R^{C6} also have the same meanings as those of R²¹ to R²⁴ in formula (2). n^{C3} and n^{C6} each represent an integer of 0 to 3. n^{C4} and n^{C5} each represent an integer of 0 to 4. When there are two or more R^{C3}s, R^{C4}s, R^{C5}s, or R^{C6}s, the respective R^{C3}s, R^{C4}s, R^{C5}s, or R^{C6}s may be the same or different from each other, and they may bond to each other to form a ring respectively. R^{C3}, R^{C4}, R^{C5}, and R^{C6} each are preferably an alkyl group, an aryl group, a hetero aryl group, and a halogen atom.

Next, the compound represented by formula (10) will be explained.

M^{B1}, Y^{B2}, Y^{B3}, R^{B1}, R^{B2}, R^{B3}, R^{B4}, L^{B5}, n^{B3}, X^{B1}, and X^{B2} each have the same meanings as M²¹, Y²², Y²³, R²¹, R²², R²³, R²⁴, L²⁵, n²¹, X²¹, and X²² in formula (2) respectively, with the same preferable ranges. Y^{B1} represents a linking group that is the same as Y²¹ in formula (2), preferably a vinyl group that substitutes with 1- and 2-positions, a phenylene ring, a pyridine ring, a pyrazine ring, a pyrimidine ring, or a methylene group having 2 to 8 carbon atoms. R^{B5} and R^{B6} each represent a hydrogen atom or a substituent. Examples of the substituent include the alkyl group, aryl group, and heterocyclic group illustrated as examples of the substituent of R²¹ to R²⁴ in formula (2). However, Y^{B1} does not link to R^{B5} or R^{B6}. n^{B1} and n^{B2} each represent an integer of 0 to 1.

Next, the compound represented by formula (12) will be explained.

The substituents represented by R^{D1}, R^{D2}, R^{D3}, and R^{D4} each have the same meanings as R^{B5} and R^{B6} in formula (10) with the same preferable ranges. n^{D1} and n^{D2} each represent an integer of 0 to 4. Y^{D1} represents a vinyl group that substitutes with 1- and 2-positions, a phenylene ring, a pyridine ring, a pyrazine ring, a pyrimidine ring, or a methylene group having 1 to 8 carbon atoms.

A preferable embodiment of the metal complex having a tridentate ligand according to the present invention is illustrated by formula (8).

Next, the compound represented by formula (8) will be explained.

M⁸¹ has the same meaning as that of the aforementioned M¹¹, with the same preferable range.

L⁸¹, L⁸², and L⁸³ have the same meanings as those of the aforementioned L¹¹, L¹², and L¹⁴, respectively, with the same preferable ranges.

Y⁸¹ and Y⁸² have the same meanings as those of the aforementioned Y¹¹ and Y¹², respectively, with the same preferable ranges.

L⁸⁵ represents a ligand to coordinate to M⁸¹. L⁸⁵ is preferably a monodentate to tridentate ligand, and more preferably a monodentate to tridentate, anionic ligand. The monodentate to tridentate, anionic ligand is not particularly restricted, but preferably a halogen ligand, a tridentate ligand formed by L⁸¹, Y⁸¹, L⁸², Y82, and L⁸³, and more preferably a tridentate ligand formed by L⁸¹, Y⁸¹, L⁸², Y⁸² and L⁸³. L⁸⁵ does not directly bond to L⁸¹ or L⁸³, but bonds to via the metal. The coordination numbers and ligand numbers do not exceed the coordination number of the metal.

n⁸¹ represents from 0 to 5. When M⁸¹ is a metal that has a coordination number of 4, n⁸¹ is 1 and L⁸⁵ is a monodentate ligand. When M⁸¹ is a metal that has a coordination number of 6, n⁸¹ is preferably from 1 to 3, more preferably 1 or 3, and furthermore preferably 1. When M⁸¹ is a metal that has a coordination number of 6 and n⁸¹ is 1, L⁸⁵ is a tridentate ligand. When M⁸¹ is a metal that has a coordination number of 6 and n⁸¹ is 2, L⁸⁵s are a monodentate ligand and a bidentate ligand. When M⁸¹ is a metal that has a coordination number of 6 and n⁸¹ is 3, L⁸⁵ is a monodentate ligand. When M⁸¹ is a metal that has a coordination number of 8, n⁸¹ is preferably from 1 to 5, more preferably 1 or 2, and furthermore preferably 1. When M⁸¹ is a metal that has a coordination number of 8 and n⁸¹ is 1, L⁸⁵ is a pentadentate ligand; when n⁸¹ is 2, L⁸⁵s are a tridentate ligand and a bidentate ligand; when n⁸¹ is 3, L⁸⁵s are a tridentate ligand and two monodentate ligands, or they are two bidentate ligands and a monodentate ligand; when n⁸¹ is 4, L⁸⁵s are a bidentate ligand and three monodentate ligands; when n⁸¹ is 5, L⁸⁵s are five monodentate ligands. When n⁸¹ is 2 or more, plural L⁸⁵s may be the same or different from each other.

A preferable embodiment of the compound represented by formula (8) is when L⁸¹, L⁸² and L⁸³ in formula (8) each represent an aromatic carbocycle or heterocycle to coordinate to M⁸¹ via a carbon atom, or a nitrogen-containing heterocycle to coordinate to M⁸¹ via a nitrogen atom, provided that at least one of L⁸¹, L⁸² and L⁸³ is a nitrogen-containing heterocycle. Examples of the aromatic, carbocycle or heterocycle to coordinate to M⁸¹ via a carbon atom, and nitrogen-containing heterocycle to coordinate to M⁸¹ via a nitrogen atom are the same as the examples of the ligands to coordinate to M¹¹ via a carbon atom and the ligands to coordinate to M¹¹ via a nitrogen atom, which are illustrated in formula (1), with the same preferable ranges. Y⁸¹ and Y⁸² each are preferably a single bond or a methylene group.

Other preferable embodiments of the compound represented by formula (8) are those represented by formula (13) or (14).

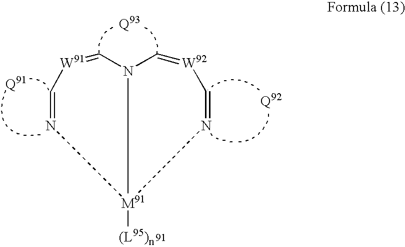

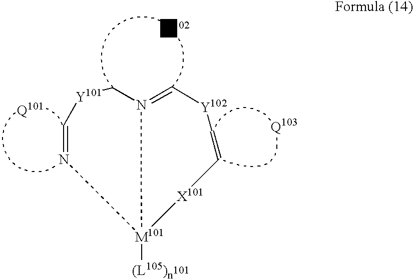

Next, the compound represented by formula (13) will be explained.

M⁹¹ has the same meaning as that of the aforementioned M⁸¹, with the same preferable range.

Q⁹¹ and Q⁹² each represent a group to form a nitrogen-containing heterocycle (a ring containing a nitrogen to coordinate to M⁹¹). The nitrogen-containing heterocycle formed by Q⁹¹ or Q⁹² is not particularly restricted, but preferably a pyridine ring, a pyrazine ring, a pyrimidine ring, a pyridazine ring, a triazine ring, a thiazole ring, an oxazole ring, a pyrrole ring, a pyrazole ring, an imidazole ring, or a triazole ring, or a condensed ring containing any of these rings (e.g., quinoline, benzoxazole, benzimidazole, and indolenine rings); or a tautomer of any of these rings. Further, these rings may be further substituted with a substituent.

The nitrogen-containing heterocycle formed by Q⁹¹ or Q⁹² is preferably a pyridine ring, a pyrazole ring, a thiazole ring, an imidazole ring, or a pyrrole ring, or a condensed ring containing any of these rings (e.g., quinoline, benzothiazole, benzimidazole, and indolenine rings) or a tautomer of any of these rings, more preferably a pyridine ring, a pyrrole ring, a condensed ring containing any of these rings (e.g., quinoline ring), or a tautomer of any of these rings; still more preferably a pyridine ring and a condensed ring containing a pyridine ring (e.g., quinoline ring), and particularly preferably a pyridine ring.

Q⁹³ represents a group to form a nitrogen-containing heterocycle (a ring containing a nitrogen to coordinate to M⁹¹). The nitrogen-containing heterocycle formed by Q⁹³ is not particularly restricted, but preferably a tautomer of a pyrrole, imidazole, or triazole ring or a condensed ring containing any of these rings (e.g., benzpyrrole ring), and more preferably a tautomer of a pyrrole ring, or a tautomer of a condensed ring containing a pyrrole ring (e.g., benzpyrrole ring). Further, these rings may be further substituted with a substituent.

W⁹¹ and W⁹² have the same meanings as those of the aforementioned W⁵¹ and W⁵², respectively, with the same preferable ranges.

L⁹⁵ has the same meaning as that of the aforementioned L⁸⁵, with the same preferable range.

n⁹¹ has the same meaning as that of the aforementioned n⁸¹, with the same preferable range.

Next, the compound represented by formula (14) will be explained.

M¹⁰¹ has the same meaning as that of the aforementioned M⁸¹, with the same preferable range.

Q¹⁰² has the same meaning as that of the aforementioned Q²¹, with the same preferable range.

Q¹⁰¹ has the same meaning as that of the aforementioned Q⁹¹, with the same preferable range.

Q¹⁰³ represents a group to form an aromatic ring. The aromatic ring formed by Q¹⁰³ is not particularly restricted, but preferably a benzene ring, a furane ring, a thiophene ring, or a pyrrole ring, or a condensed ring containing any of these rings (e.g., naphthalene ring); more preferably a benzene ring or a condensed ring containing a benzene ring (e.g., naphthalene ring); and particularly preferably a benzene ring.

Y¹⁰¹ and Y¹⁰² each have the same meanings as those of the aforementioned Y²², with the same preferable ranges.

L¹⁰⁵ has the same meaning as that of the aforementioned L⁸⁵, with the same preferable range. n¹⁰¹ has the same meaning as that of the aforementioned n⁸¹, with the same preferable range.

X¹⁰¹ has the same meaning as that of the aforementioned X²¹, with the same preferable range.

The metal complex as the luminescent material that can be used in the present invention may be a low molecular compound, or may be an oligomer compound or a polymer compound having a mass-average molecular mass calculated in terms of polystyrene preferably in the range of 1,000 to 5,000,000, more preferably in the range of 2,000 to 1,000,000, and furthermore preferably in the range of 3,000 to 100,000. With respect to the polymer compound, the structure represented by any of formulas (1) to (14) may be contained in a main chain of the polymer, or in a side chain of the polymer. Further, the polymer compound may be a homopolymer or a copolymer. The metal complex as the luminescent material that can be used in the present invention is preferably a low molecular compound.

Another preferable embodiment of the metal complex having a tridentate ligand for use in the present invention is a metal complex represented by formula (X1). Among the metal complexes represented by formula (X1), metal complexes represented by formula (X2) are preferable, and metal complexes represented by formula (X3) are more preferable.

The compound represented by formula (X1) will be explained.

M^{X1} represents a metal ion. The metal ion is not particularly restricted, but a monovalent to trivalent metal ion is preferable, a divalent or trivalent metal ion is more preferable, and a trivalent metal ion is furthermore preferable. Specifically, platinum, iridium, rhenium, palladium, rhodium, ruthenium, copper, europium, gadolinium, and terbium ions are preferable. Of these ions, platinum, iridium, and europium ions are more preferable, platinum and iridium ions are furthermore preferable, and an iridium ion is particularly preferable.

Q^{X11}, Q^{X12}, Q^{X13}, Q^{X14}, Q^{X15}, and Q^{X16} each represent an atom to coordinate to M^{X1} or an atomic group having an atom to coordinate to M^{X1}. When Q^{X11}, Q^{X12}, Q^{X13}, Q^{X14}, Q^{X15}, or Q^{X16} represents an atom to coordinate to M^{X1}, specific examples of the atom include a carbon atom, a nitrogen atom, an oxygen atom, a silicon atom, a phosphorus atom, and a sulfur atom; and preferably, the atom is a nitrogen atom, an oxygen atom, a sulfur atom, or a phosphorus atom, and more preferably a nitrogen atom or an oxygen atom.

When Q^{X11}, Q^{X12}, Q^{X13}, Q^{X14}, Q^{X15}, or Q^{X16} represents an atomic group having an atom to coordinate to M^{X1}, examples of the atomic group to coordinate to M^{X1} via a carbon atom include an imino group, an aromatic hydrocarbon ring group (e.g., benzene, naphthalene), a heterocyclic ring group (e.g., thiophene, pyridine, pyrazine, pyrimidine, pyridazine, triazine, thiazole, oxazole, pyrrole, imidazole, pyrazole, triazole), a condensed ring including any of these rings, and a tautomer of any of these rings. Further, these rings may be further substituted with a substituent.

Examples of the atomic group to coordinate to M^{X1} via a nitrogen atom include a nitrogen-containing heterocyclic ring group (e.g., pyridine, pyrazine, pyrimidine, pyridazine, triazine, thiazole, oxazole, pyrrole, imidazole, pyrazole, triazole), an amino group {e.g., an alkylamino group (having carbon atoms preferably in the range of 2 to 30, more preferably in the range of 2 to 20, and particularly preferably in the range of 2 to 10; for example, methylamino), an arylamino group (for example, phenylamino), an acylamino group (having carbon atoms preferably in the range of 2 to 30, more preferably in the range of 2 to 20, and particularly preferably in the range of 2 to 10; for example, acetylamino, benzoylamino), an alkoxycarbonylamino group (having carbon atoms preferably in the range of 2 to 30, more preferably in the range of 2 to 20, and particularly preferably in the range of 2 to 12; for example, methoxycarbonylamino), an aryloxycarbonylamino group (having carbon atoms preferably in the range of 7 to 30, more preferably in the range of 7 to 20, and particularly preferably in the range of 7 to 12; for example, phenyloxycarbonylamino), a sulfonylamino group (having carbon atoms preferably in the range of 1 to 30, more preferably in the range of 1 to 20, and particularly preferably in the range of 1 to 12; for example, methane sulfonylamino, benzene sulfonylamino)}, and an imino group. These groups may be further substituted with a substituent.

Examples of the atomic group to coordinate to M^{X1} via an oxygen atom include an alkoxy group (having carbon atoms preferably in the range of 1 to 30, more preferably in the range of 1 to 20, and particularly preferably in the range of 1 to 10; for example, methoxy, ethoxy, butoxy, 2-ethylhexyloxy), an aryloxy group (having carbon atoms preferably in the range of 6 to 30, more preferably in the range of 6 to 20, and particularly preferably in the range of 6 to 12; for example, phenyloxy, 1-naphthyloxy, 2-naphthyloxy), a heterocyclic oxy group (having carbon atoms preferably in the range of 1 to 30, more preferably in the range of 1 to 20, and particularly preferably in the range of 1 to 12; for example, pyridyloxy, pyrazyloxy, pyrimidyloxy, quinolyloxy), an acyloxy group (having carbon atoms preferably in the range of 2 to 30, more preferably in the range of 2 to 20, and particularly preferably in the range of 2 to 10; for example, acetoxy, benzoyloxy), a silyloxy group (having carbon atoms preferably in the range of 3 to 40, more preferably in the range of 3 to 30, and particularly preferably in the range of 3 to 24; for example, trimethylsilyloxy, triphenylsilyloxy), a carbonyl group (for example, ketone group, ester group, amido group), and an ether group (for example, dialkylether group, diarylether group, furyl group). These groups may be further substituted with a substituent.

Examples of the atomic group to coordinate to M^{X1} via a sulfur atom include an alkylthio group (having carbon atoms preferably in the range of 1 to 30, more preferably in the range of 1 to 20, and particularly preferably in the range of 1 to 12; for example, methylthio, ethylthio), an arylthio group (having carbon atoms preferably in the range of 6 to 30, more preferably in the range of 6 to 20, and particularly preferably in the range of 6 to 12; for example, phenylthio), a heterocyclic thio group (having carbon atoms preferably in the range of 1 to 30, more preferably in the range of 1 to 20, and particularly preferably in the range of 1 to 12; for example, pyridylthio, 2-benzimidazolylthio, 2-benzoxazolylthio, 2-benzthiazolylthio), a thiocarbonyl group (for example, thioketone group, thioester group), and a thioether group (for example, dialkylthioether group, diarylthioether group, thiofuryl group). These groups may be further substituted with a substituent.

Examples of the atomic group to coordinate to M^{X1} via a phosphorus atom include a dialkylphosphino group, a diarylphosphino group, a trialkylphosphine, a triarylphosphine, a phosphinine group. These groups may be further substituted.

As the atomic group represented by Q^{X11}, Q^{X12}, Q^{X13}, Q^{X14}, Q^{X15}, or Q^{X16}, preferred are an aromatic hydrocarbon ring group to coordinate to M^{X1} via a carbon atom, an aromatic heterocycle group to coordinate to M^{X1} via a carbon atom, a nitrogen-containing aromatic heterocycle group to coordinate to M^{X1} via a nitrogen atom, an alkyloxy group, an aryloxy group, an alkylthio group, an arylthio group, a dialkylphosphino group; more preferred are an aromatic hydrocarbon ring group to coordinate to M^{X1} via a carbon atom, an aromatic heterocycle group to coordinate to M^{X1} via a carbon atom, and a nitrogen-containing aromatic heterocycle group to coordinate to Mxl via a nitrogen atom.

L^{X11}, L^{X12}, L^{X13}, and L^{X14} each represent a single bond, a double bond, or a linking group. The linking group is not particularly restricted. Preferred examples of the linking group include a linking group comprising any of carbon, nitrogen, oxygen, sulfur, and silicon atoms. Specific examples of the linking group are shown below, but the present invention is not limited to these.

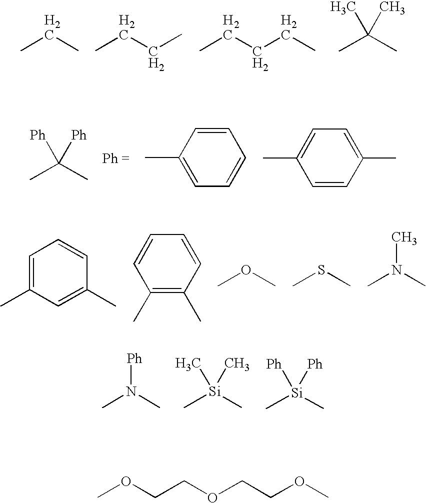

These linking groups may be further substituted by a substituent. Examples of the substituent include those explained as the substituents represented by R²¹ to R²⁴ in formula (2), with the same preferable range. As L^{X11}, L^{X12}, L^{X13}, or L^{X14}, preferred are a single bond, a dimethylmethylene group, a dimethylsilylene group.

The metal complex represented by formula (X1) is more preferably a metal complex represented by formula (X2). Next, the metal complex represented by formula (X2) will be explained.

M^{X2} has the same meaning as that of the aforementioned M^{X1} in formula (X1), with the same preferable range Y^{X21}, Y^{X2}, Y^{X23}, Y^{X24}, Y^{X5} and Y^{X26} each represent an atom to coordinate to M^{X2}. A bond between Y^{X21} and M^{X2}, a bond between Y^{X22} and M^{X2}, a bond between Y^{X23} and M^{X2}, a bond between Y^{X24} and M^{X2}, a bond between Y^{X25} and M^{X2}, and a bond between Y^{X26} and M^{X2} may each be a coordinate bond or a covalent bond. Specific examples of Y^{X21}, Y^{X22}, Y^{X23}, Y^{X24}, Y^{X25}, or Y^{X26} include a carbon atom, a nitrogen atom, an oxygen atom, a sulfur atom, a phosphorus atom, and a silicon atom; and preferred are a carbon atom and a nitrogen atom. Each of Q^{X21}, Q^{X22}, Q^{X23}, Q^{X24}, Q^{X25}, and Q^{X26} respectively represents an atomic group necessary to form an aromatic hydrocarbon ring or aromatic heterocycle together with each of Y^{X21}, Y^{X22}, Y^{X23}, Y^{X24}, Y^{X25}, and Y^{X26} respectively. Examples of the aromatic hydrocarbon ring or aromatic heterocycle formed by these groups include benzene, pyridine, pyrazine, pyrimidine, pyridazine, triazine, pyrrole, pyrazole, imidazole, triazole, oxazole, thiazole, oxadiazole, thiadiazole, thiophene, and furane rings. Preferred are benzene, pyridine, pyrazine, pyrimidine, pyrazole, imidazole, and triazole rings; more preferred are benzene, pyridine, pyrazine, pyrazole, and triazole rings; and particularly preferred are benzene and pyridine rings. These rings may further include a condensed ring, or may have a substituent.

L^{X21}, L^{X22}, L^{X23}, and L^{X24} have the same meanings as those of the aforementioned L^{X11}, L^{X12}, L^{X13}, and L^{X14} in formula (X1), with the same preferable ranges.

The metal complex represented by formula (X1) is furthermore preferably a metal complex represented by formula (X3). Next, the metal complex represented by formula (X3) will be explained.

M^{X3} has the same meaning as that of the aforementioned M^{X1} in formula (X1), with the same preferable range. Y^{X31}, Y^{X32}, Y^{X33}, Y^{X34}, y^{X35} and Y^{X36} each represent an atom to coordinate to M^{X3}. A bond between Y^{X31} and M^{X3}, a bond between Y^{X32} and M^{X3}, a bond between Y^{X33} and M^{X3}, a bond between Y^{X34} and M^{X3}, a bond between Y^{X35} and M^{X3}, and a bond between Y^{X36} and M^{X3} may each be a coordinate bond or a covalent bond. Specific examples of Y^{X31}, Y^{X32}, Y^{X33}, Y^{X34}, Y^{X35}, or Y^{X36} include a carbon atom, a nitrogen atom, and a phosphorus atom; and preferred are a carbon atom and a nitrogen atom. L^{X31}, L^{X32}, L^{X33}, and L^{X34} have the same meanings as those of the aforementioned L^{X11}, L^{X12}, L^{X13}, and L^{X14} in formula (X1), with the same preferable ranges.

Specific examples of the compound of the present invention are shown below, but the present invention is not limited to these compounds.

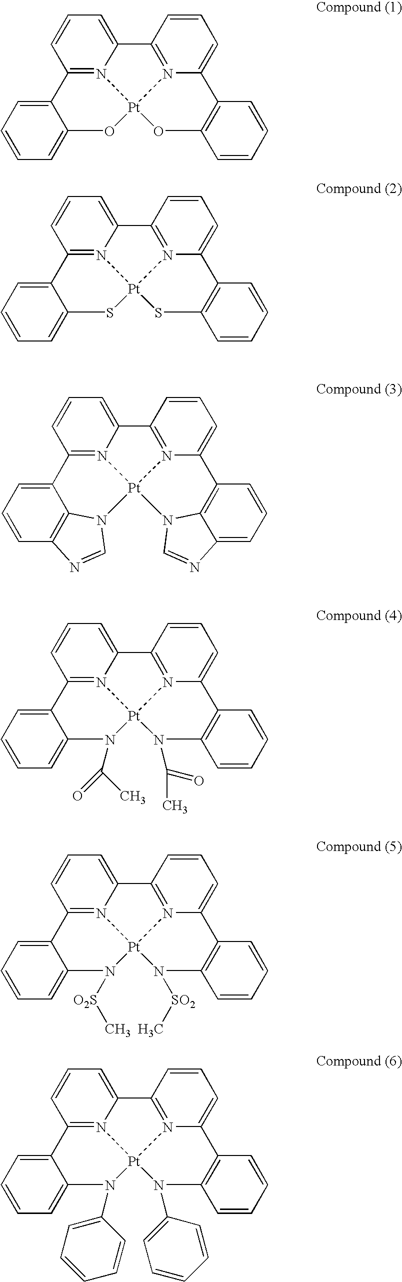

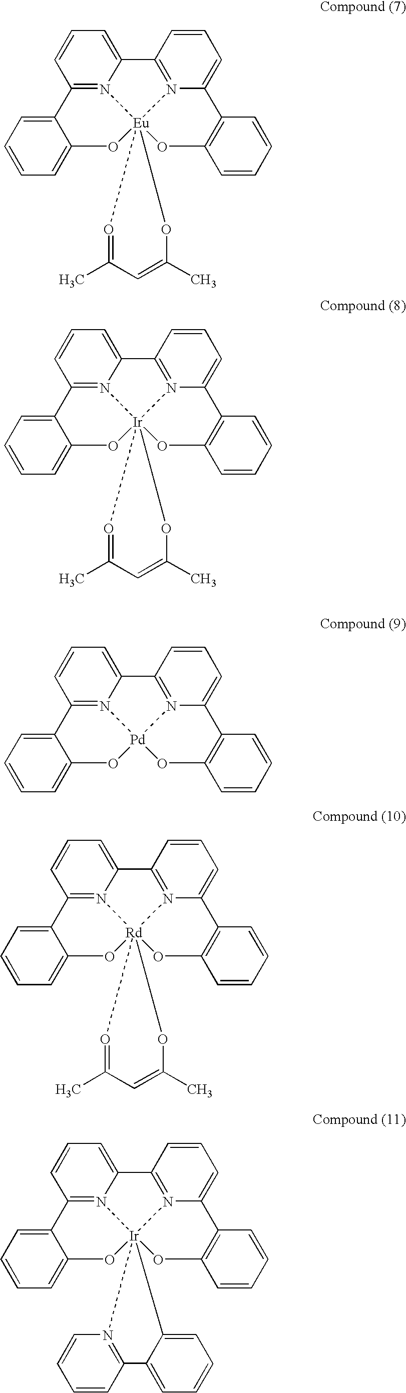

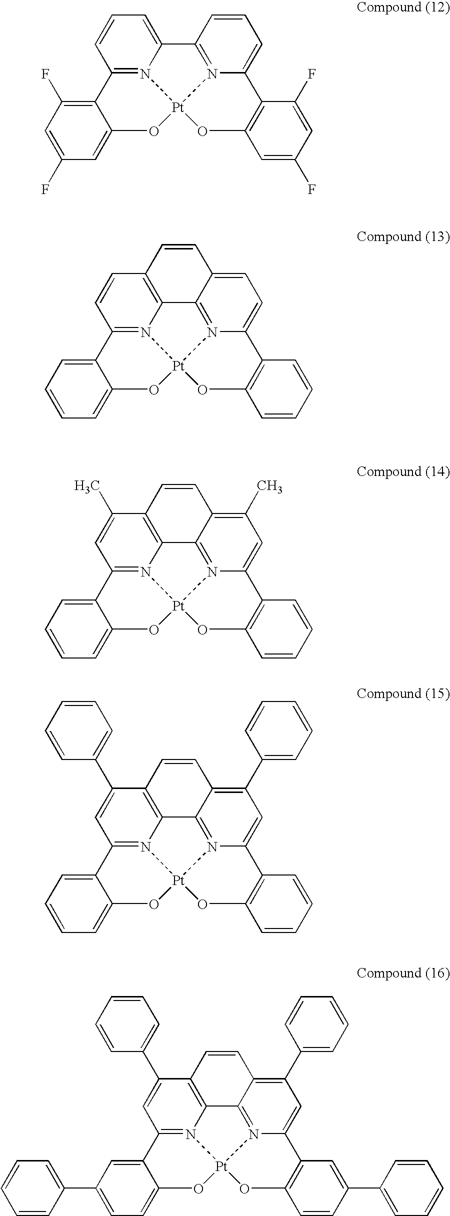

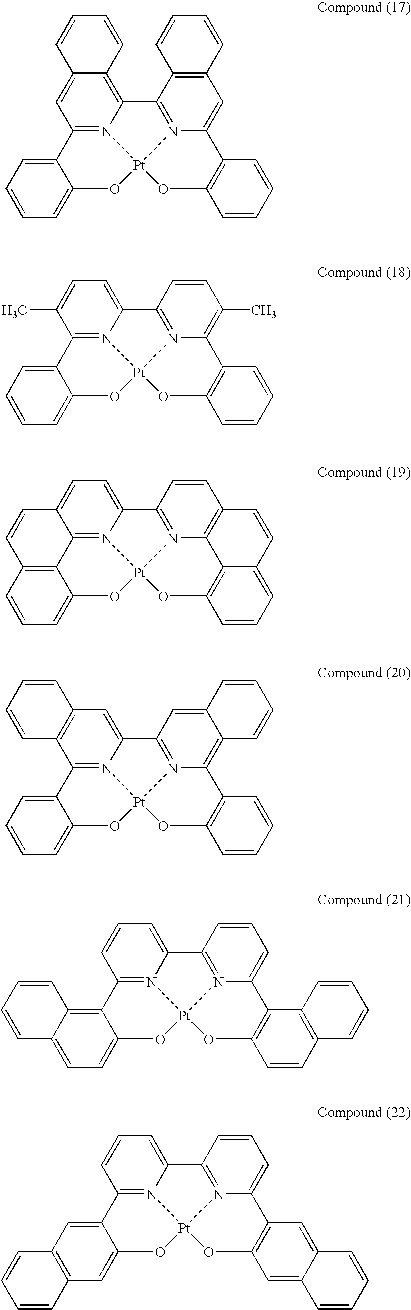

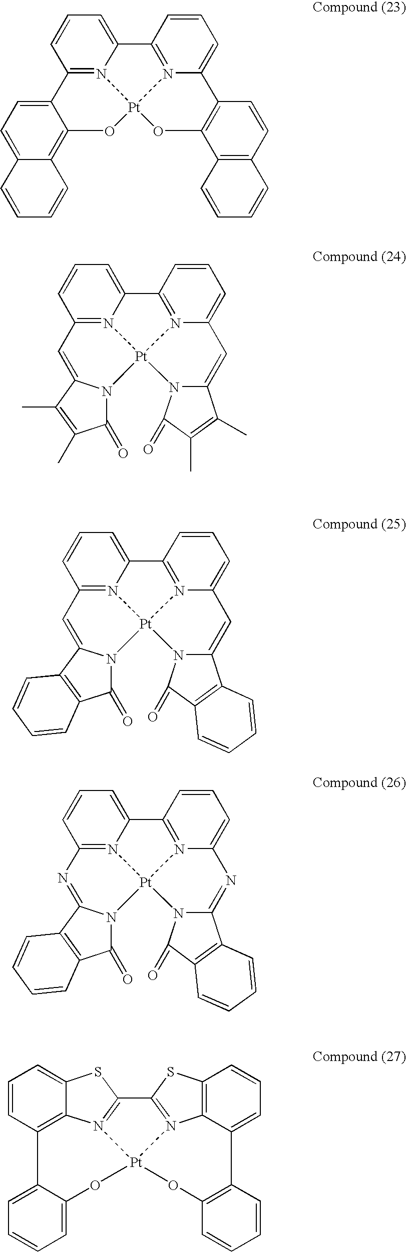

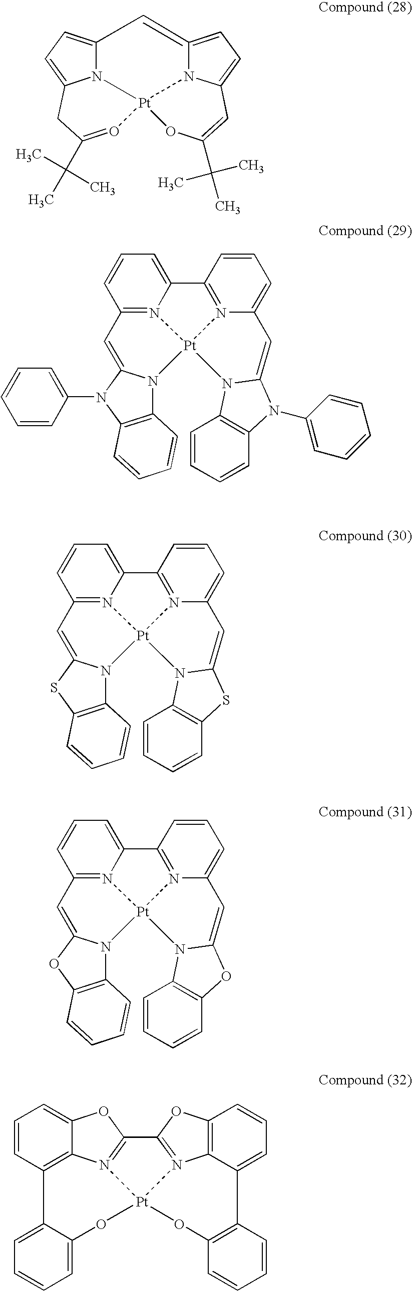

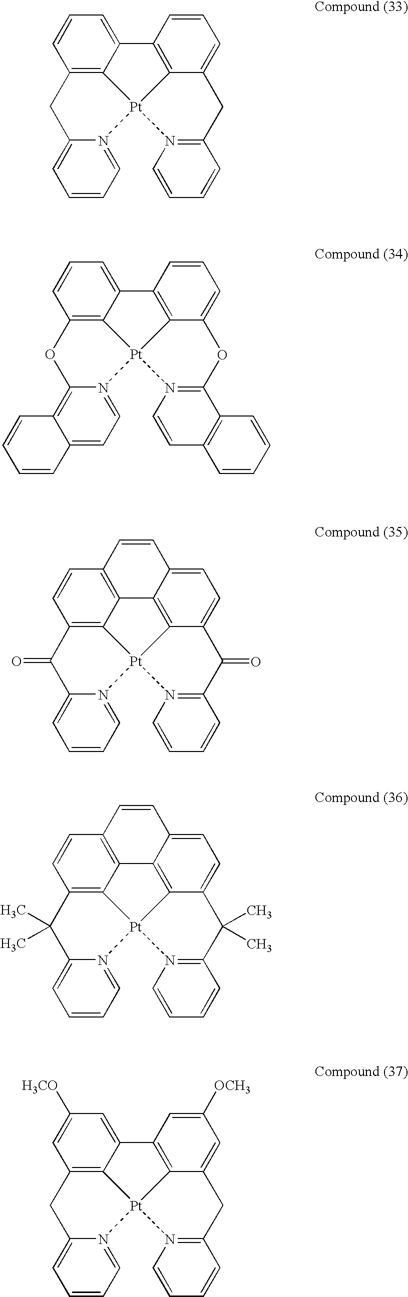

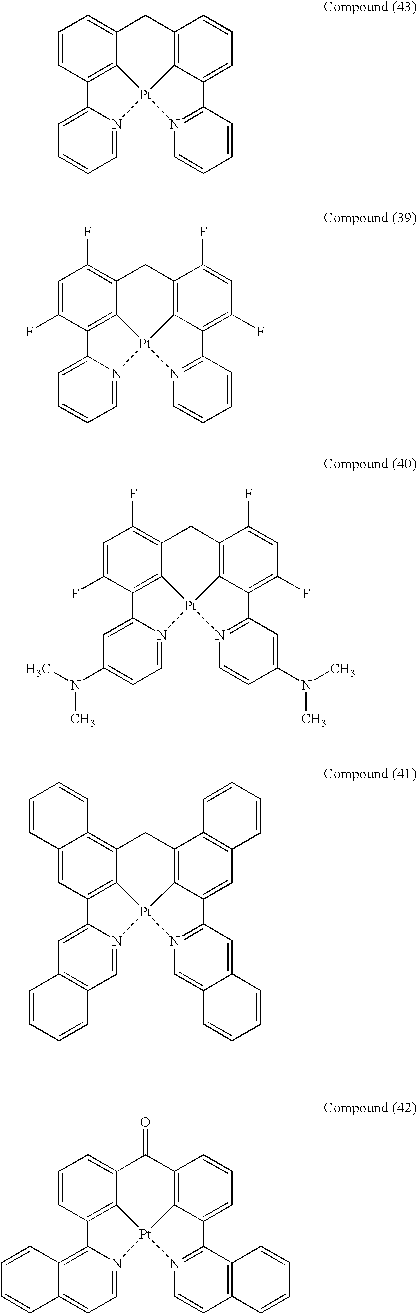

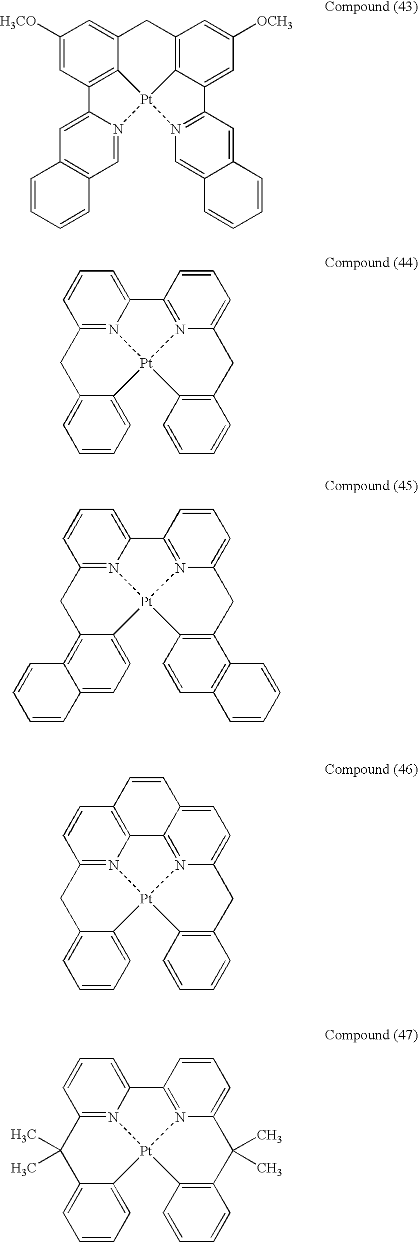

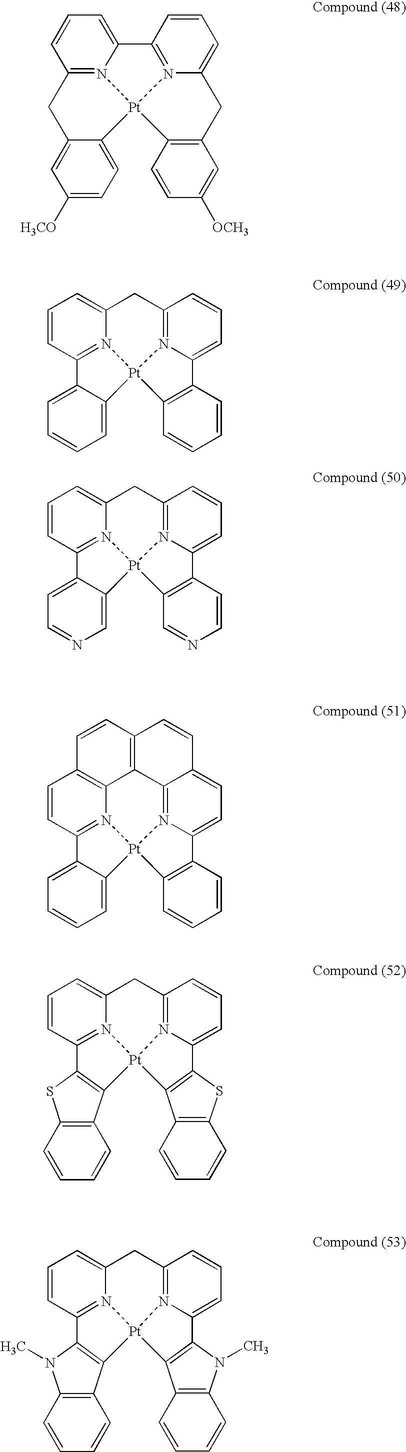

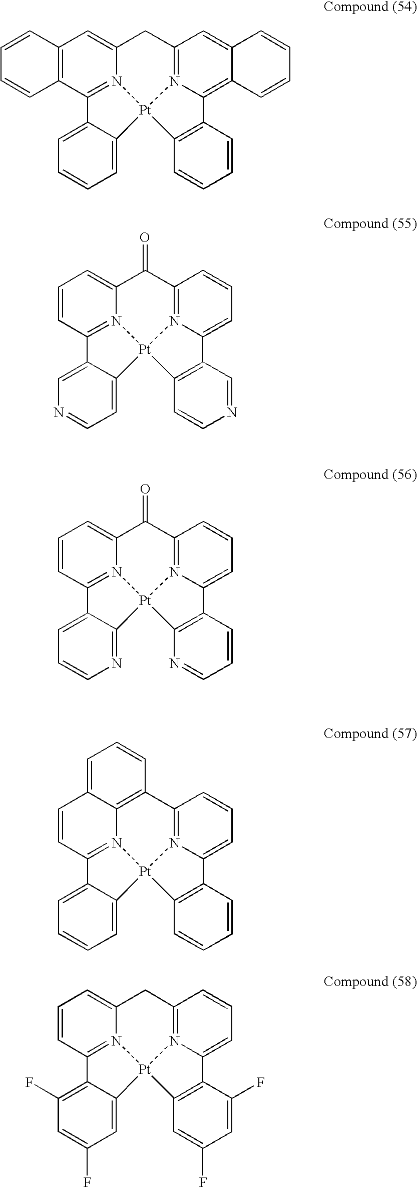

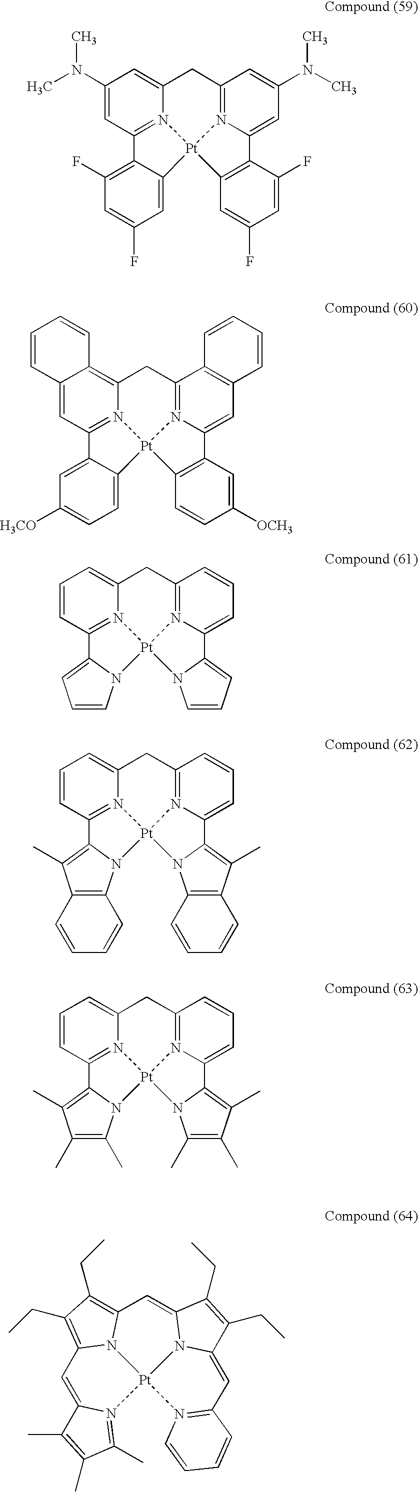

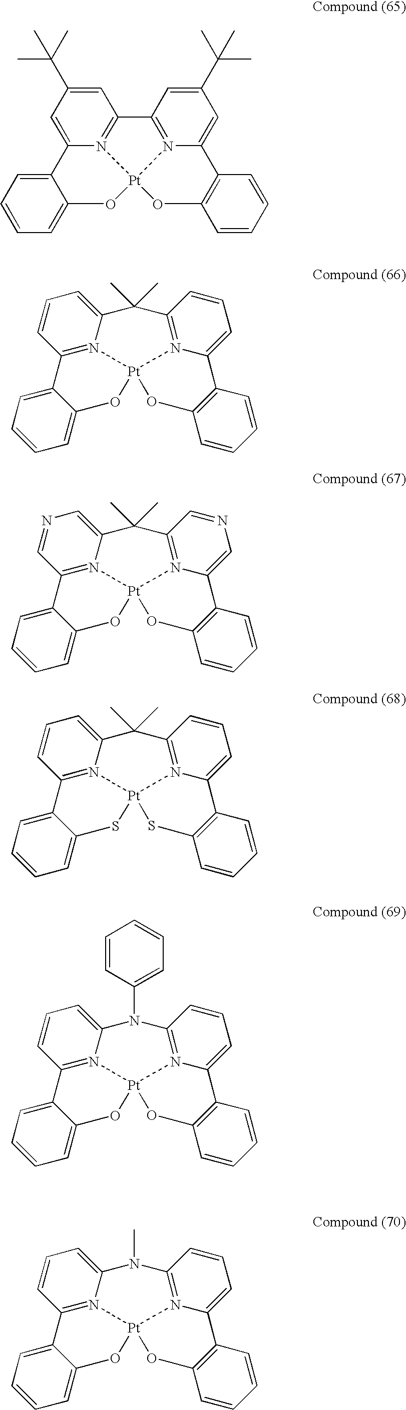

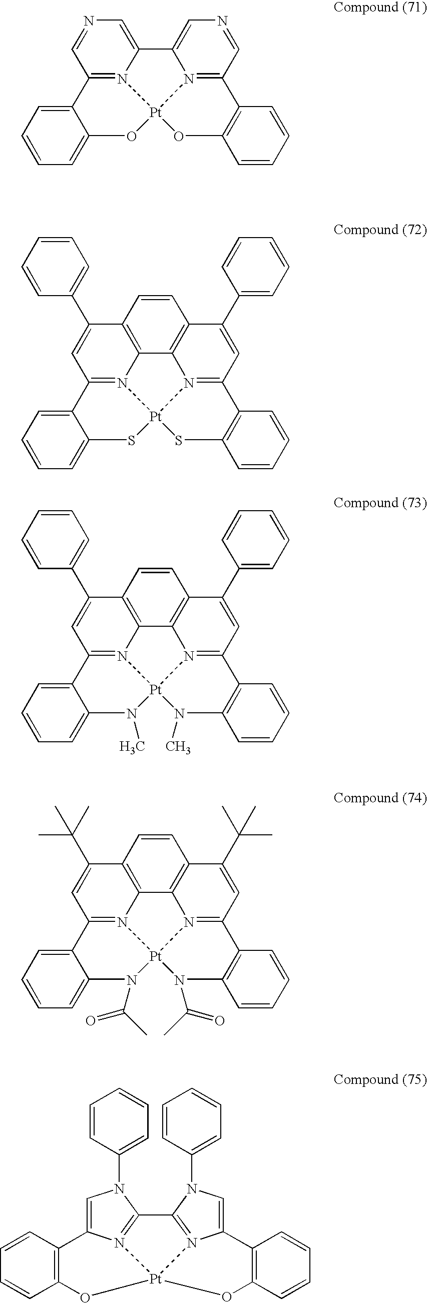

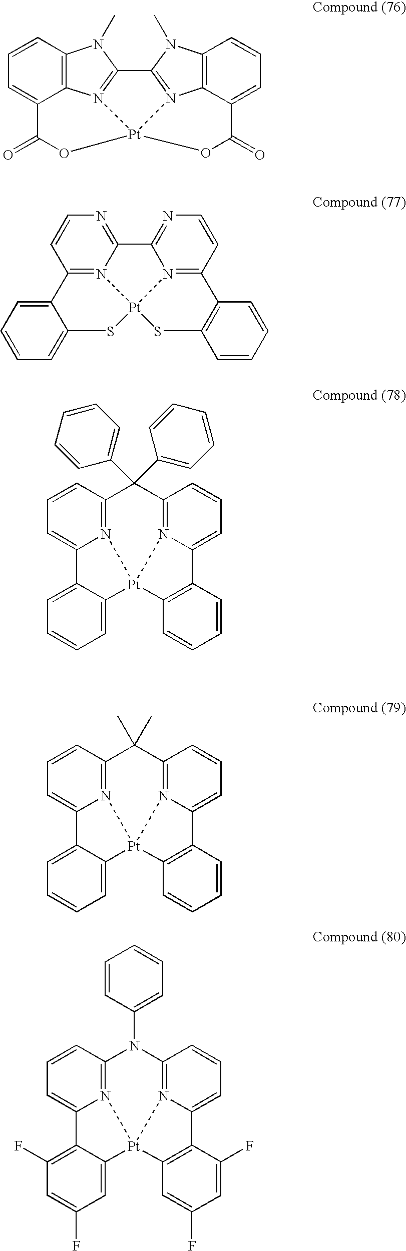

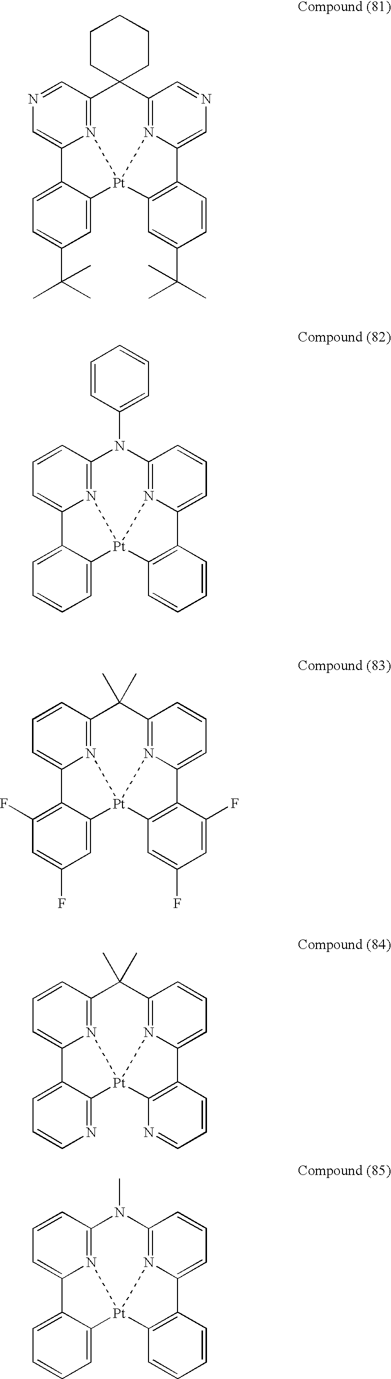

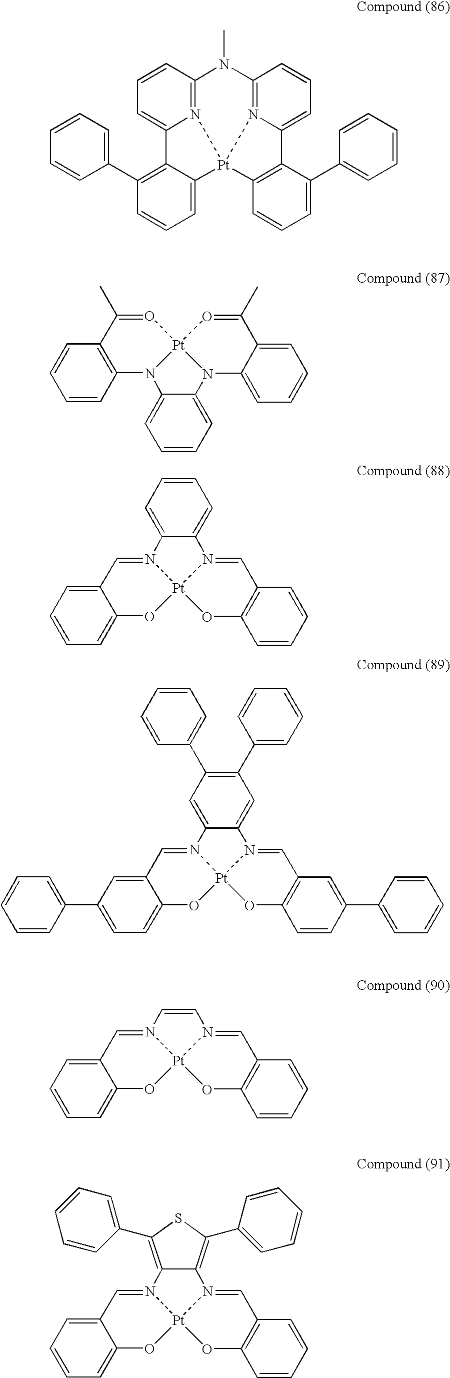

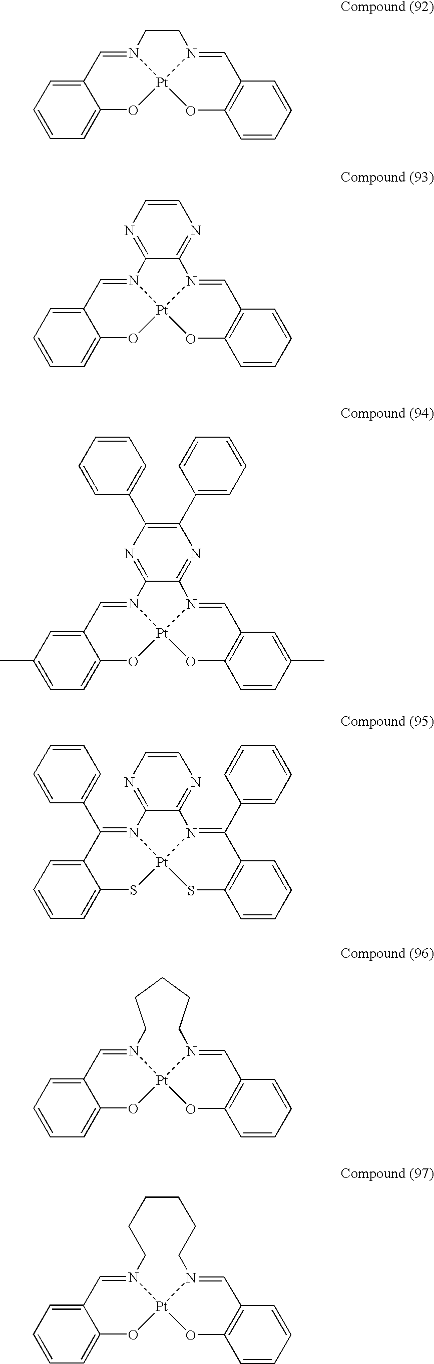

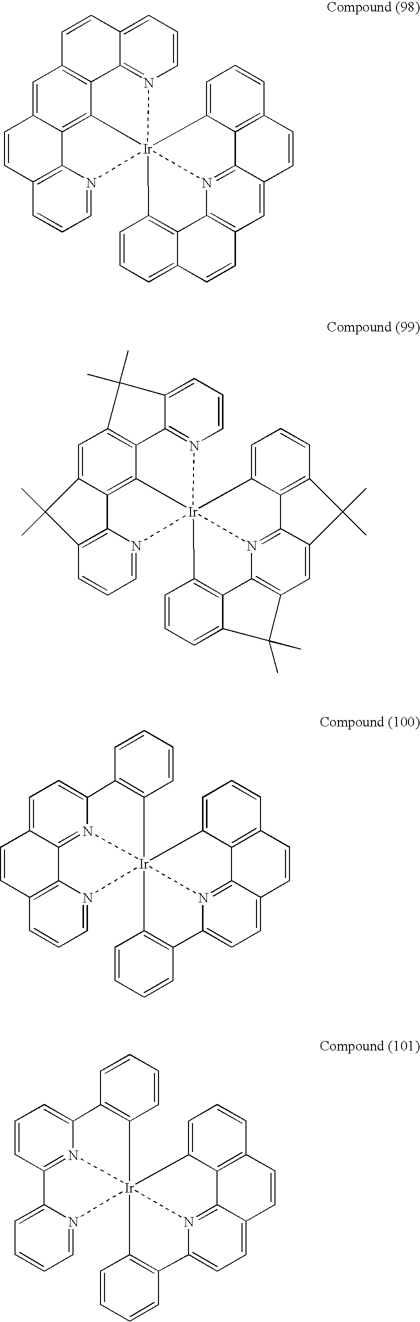

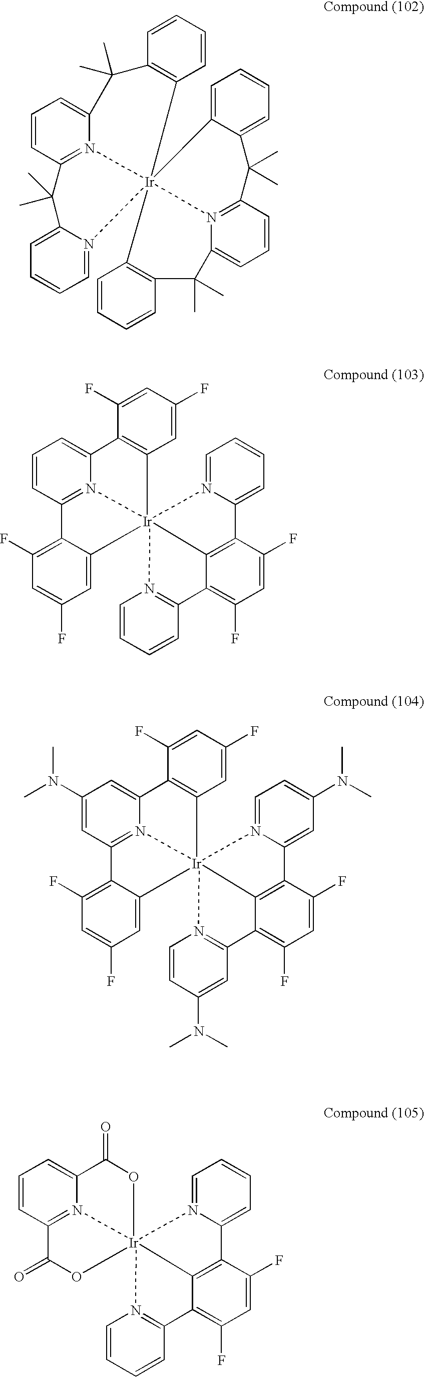

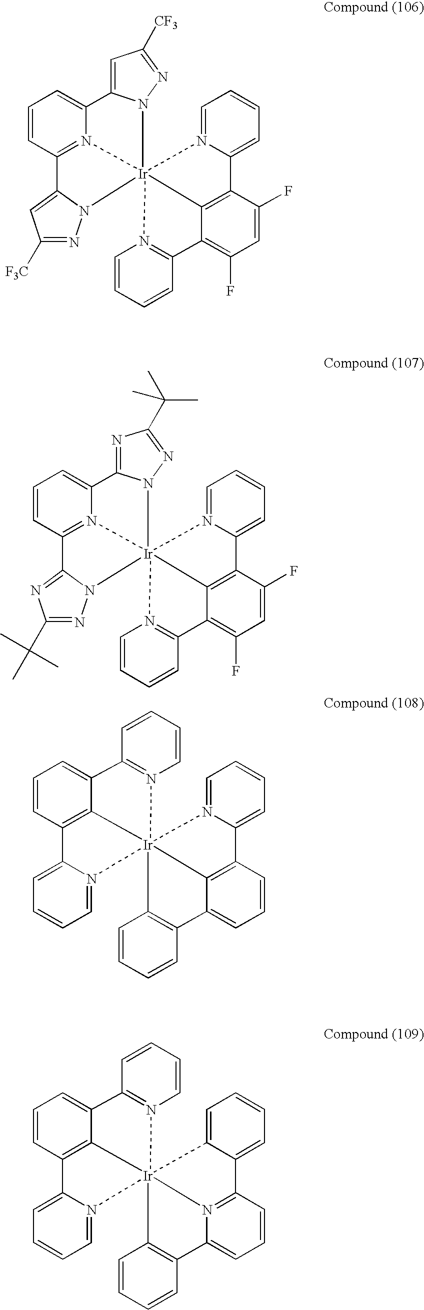

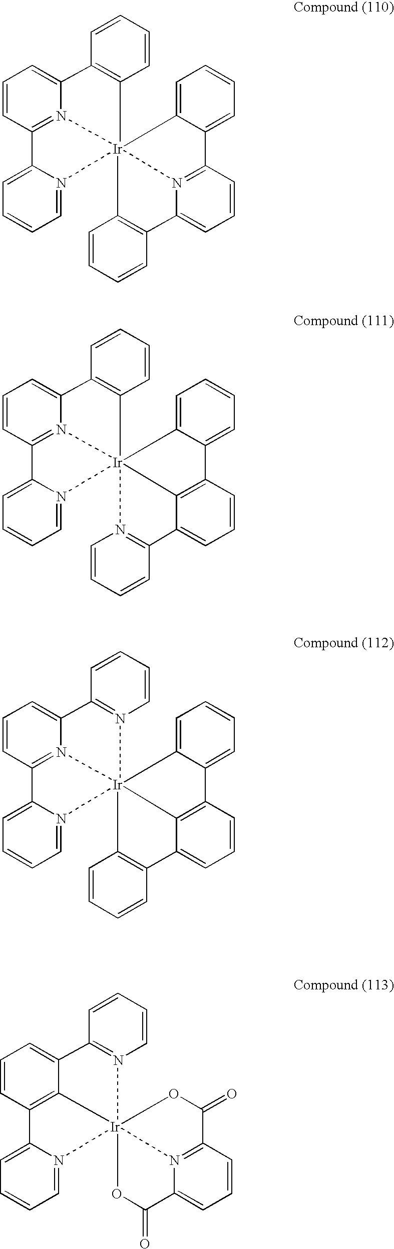

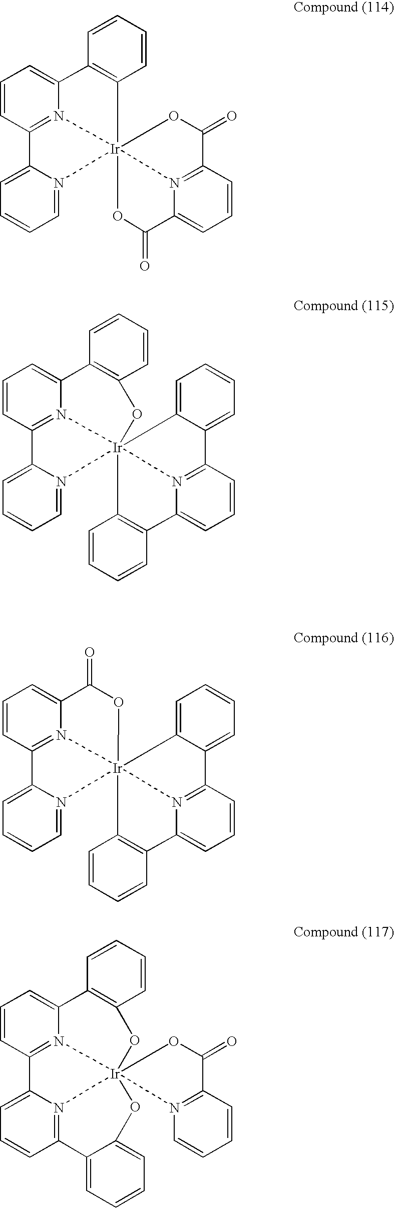

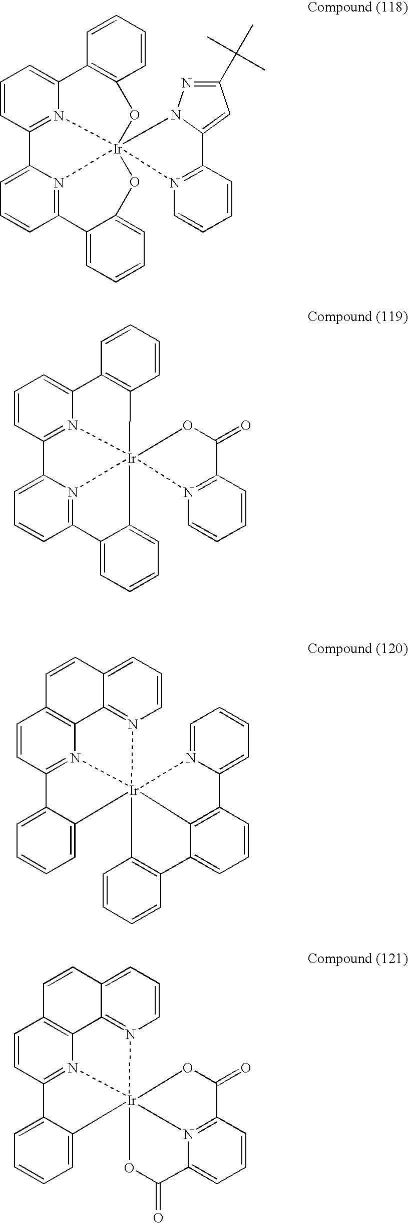

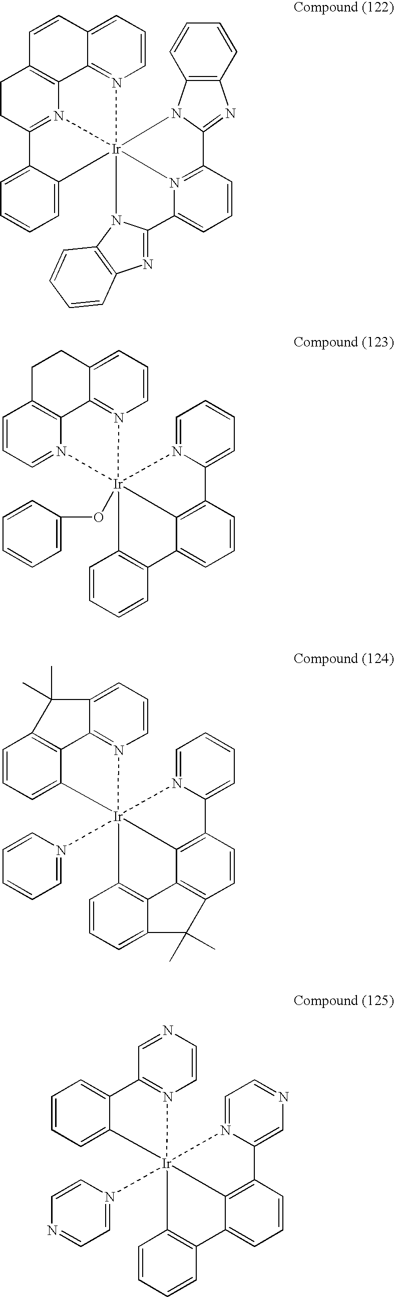

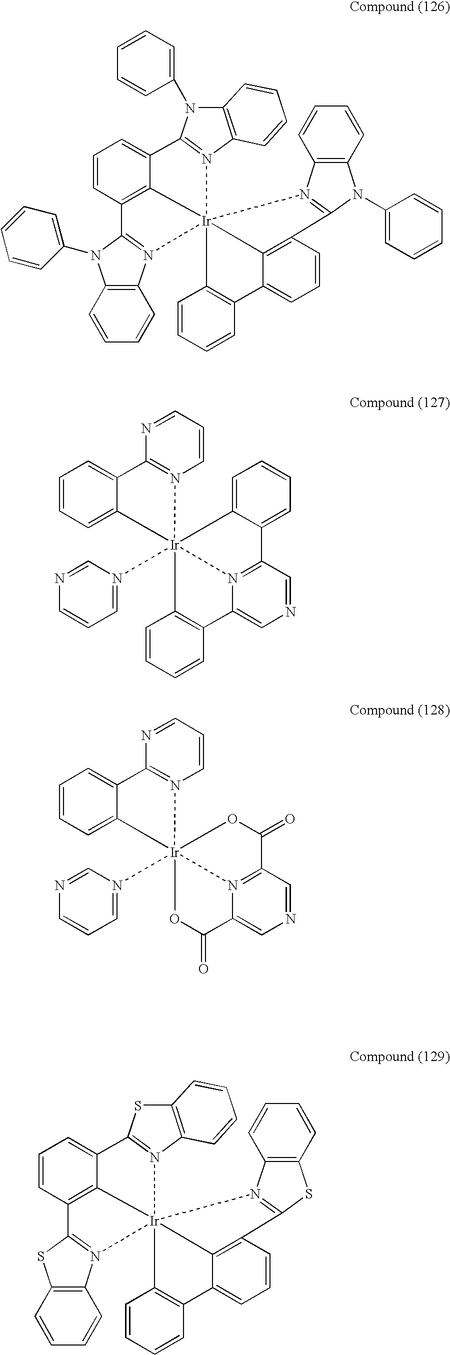

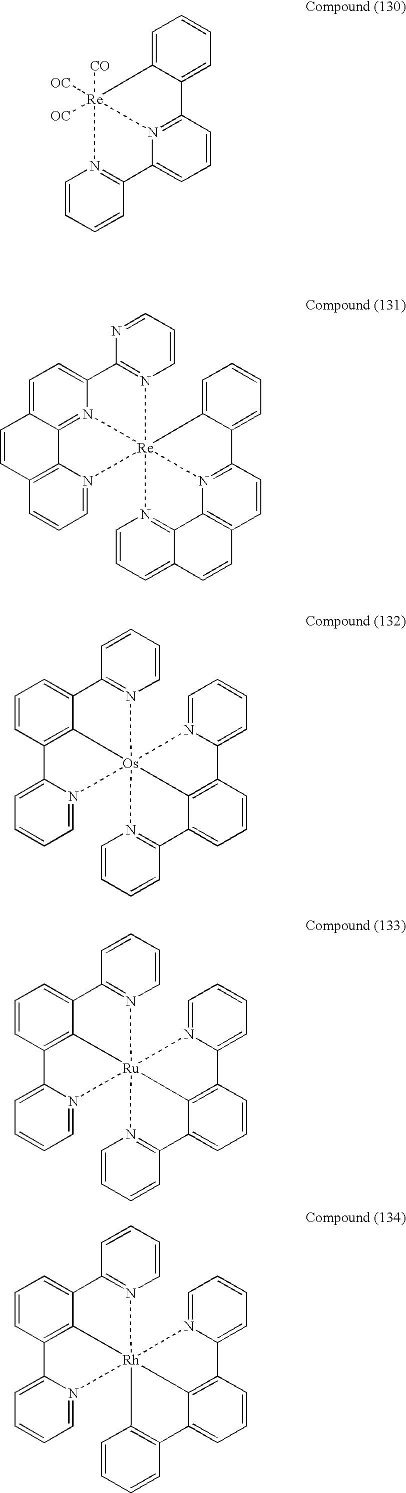

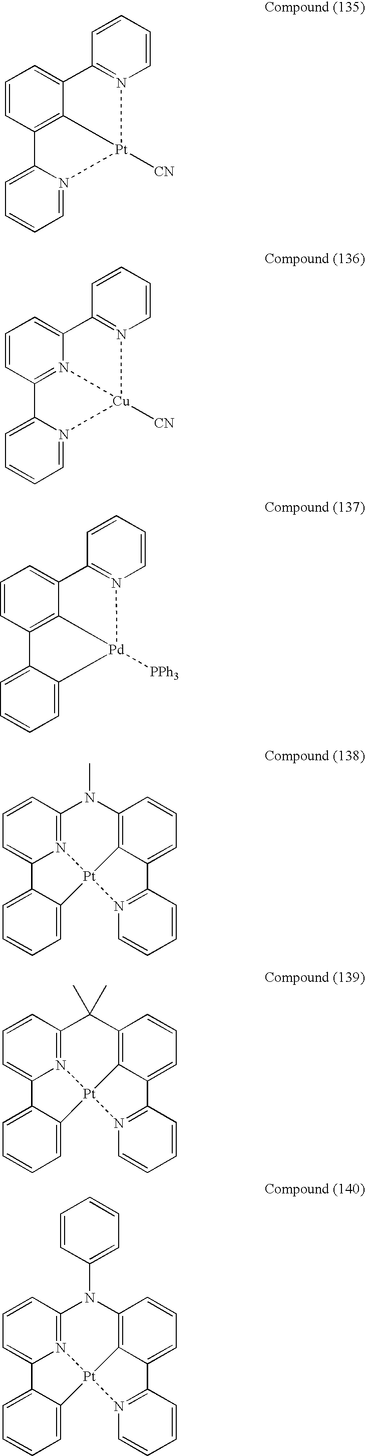

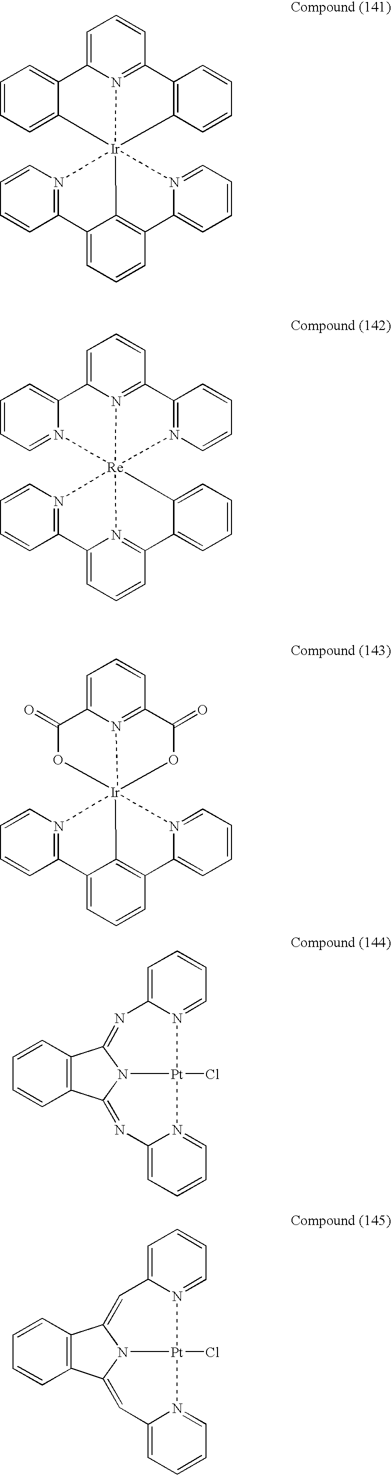

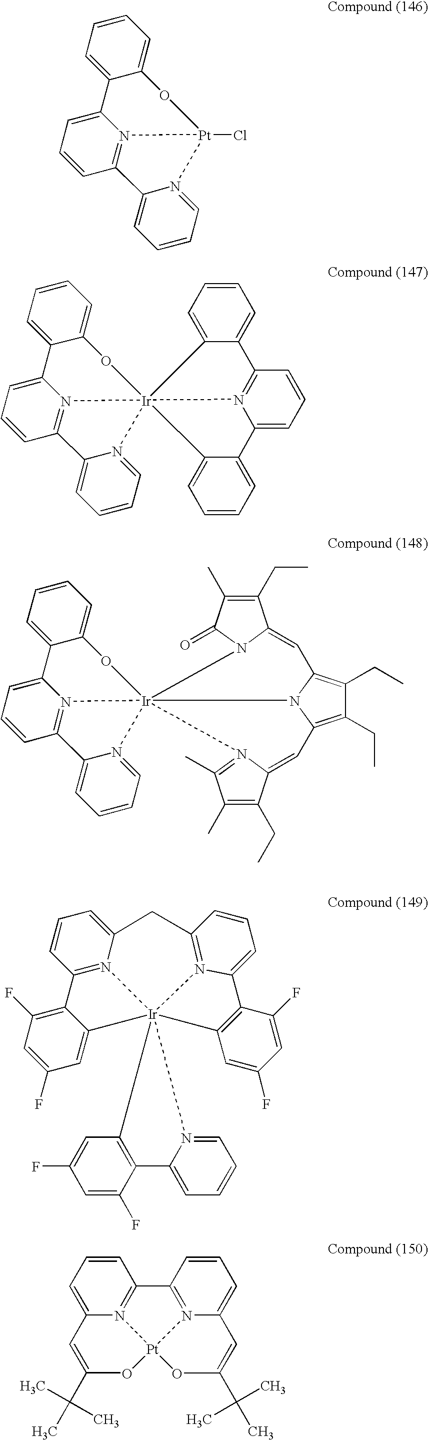

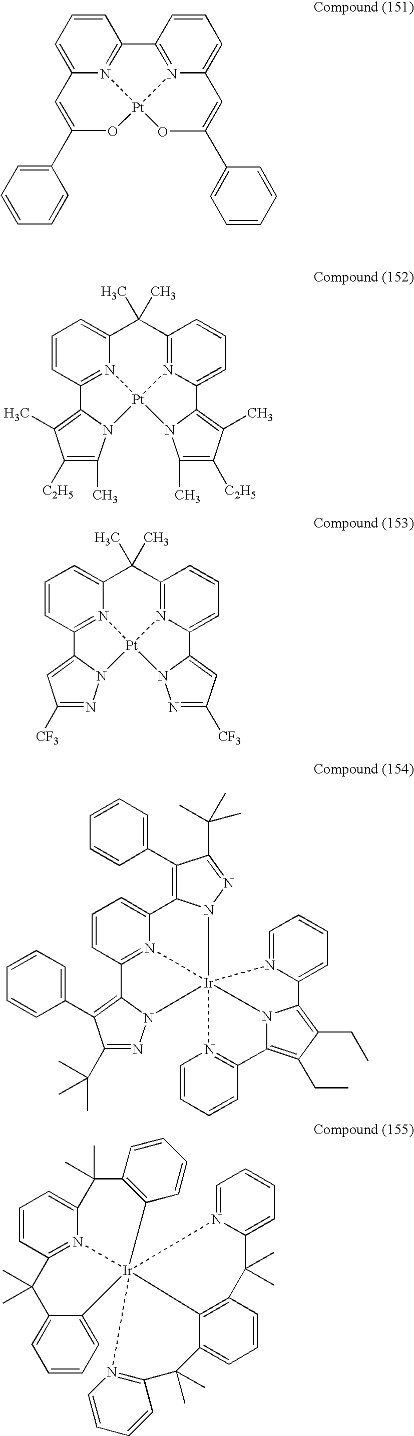

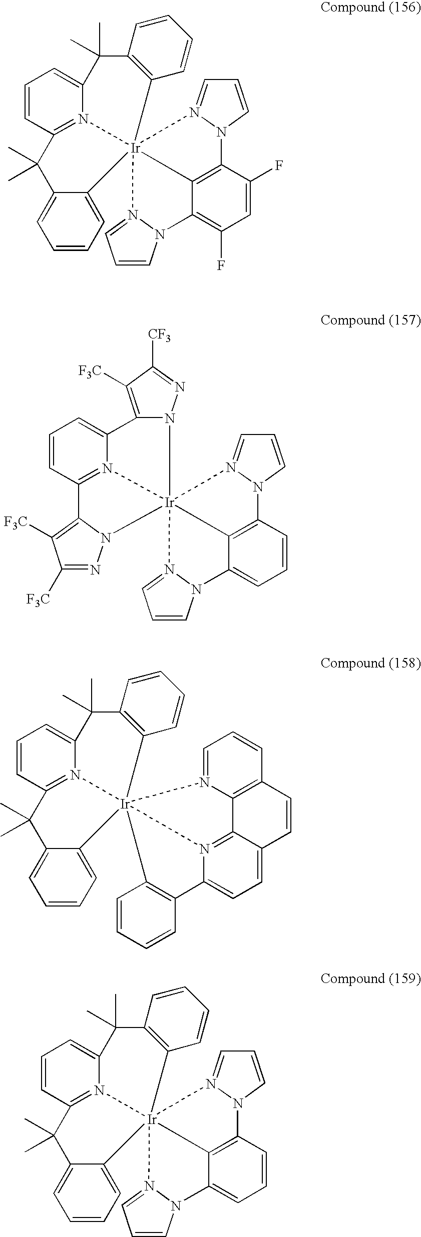

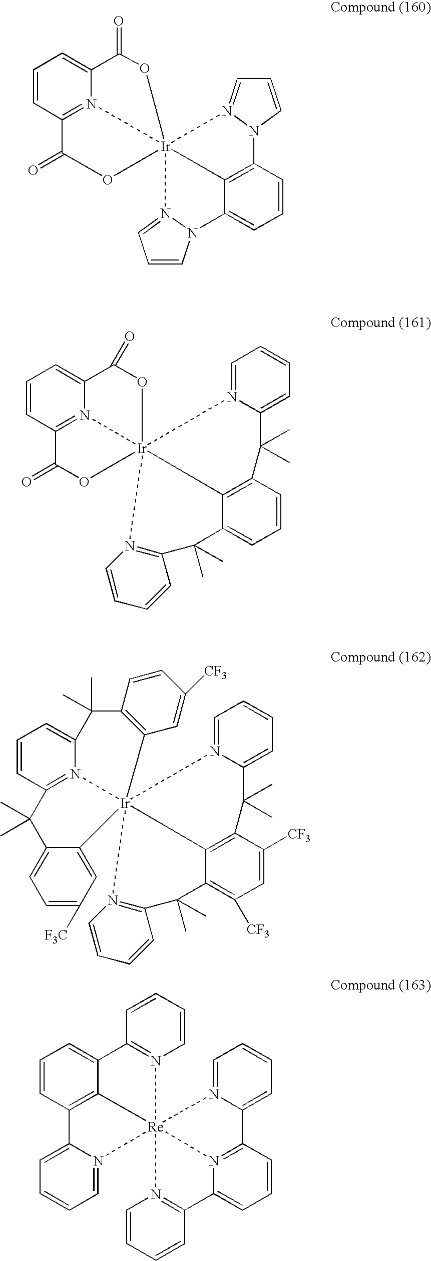

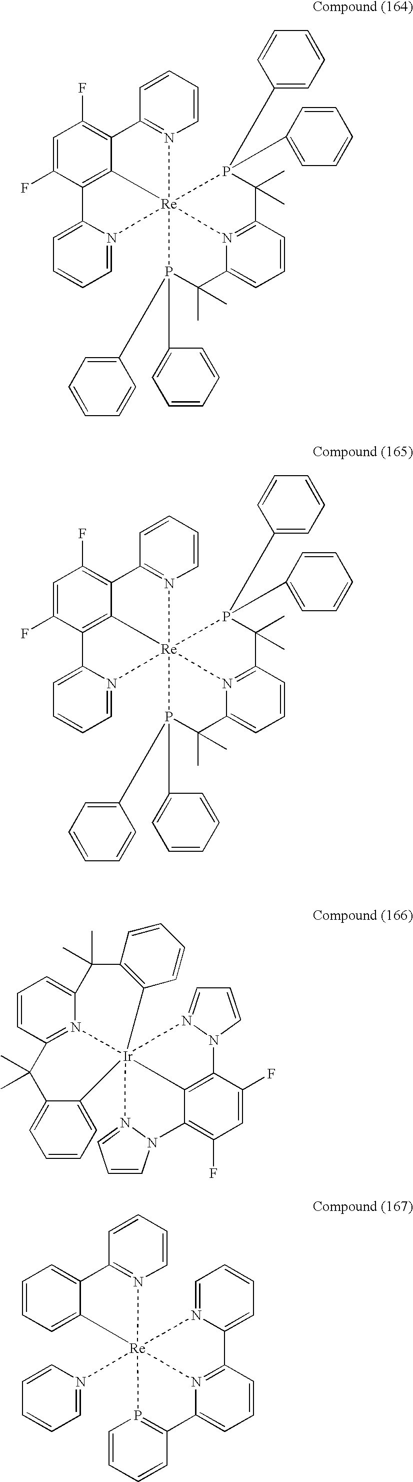

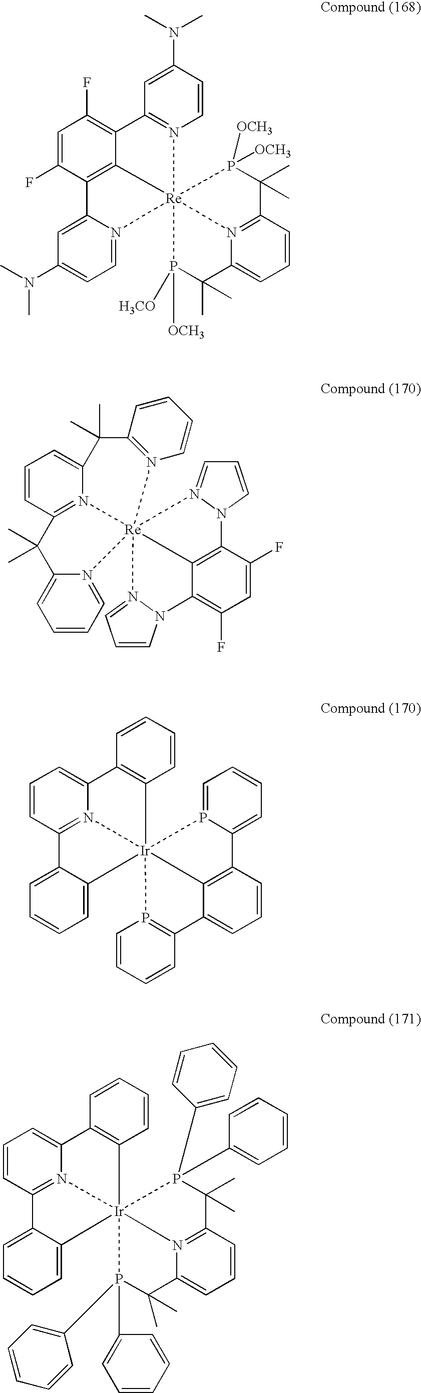

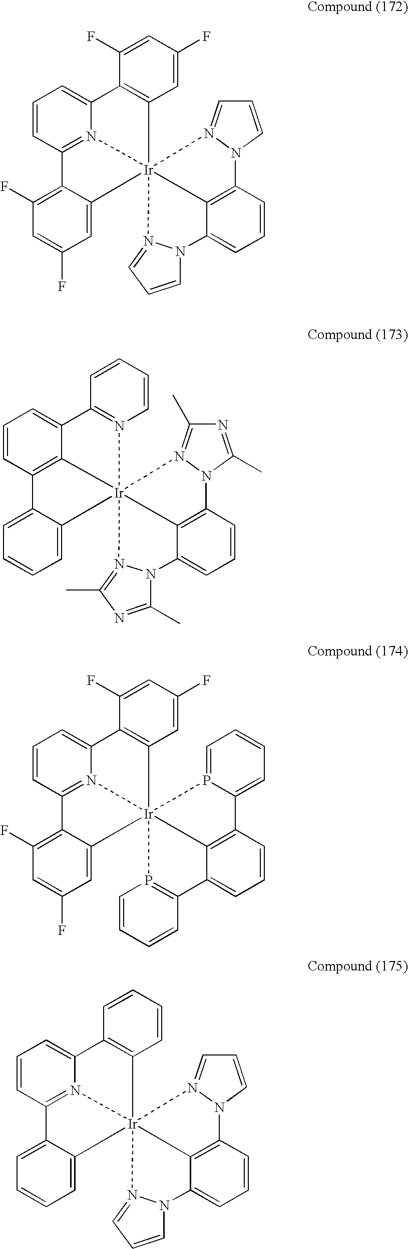

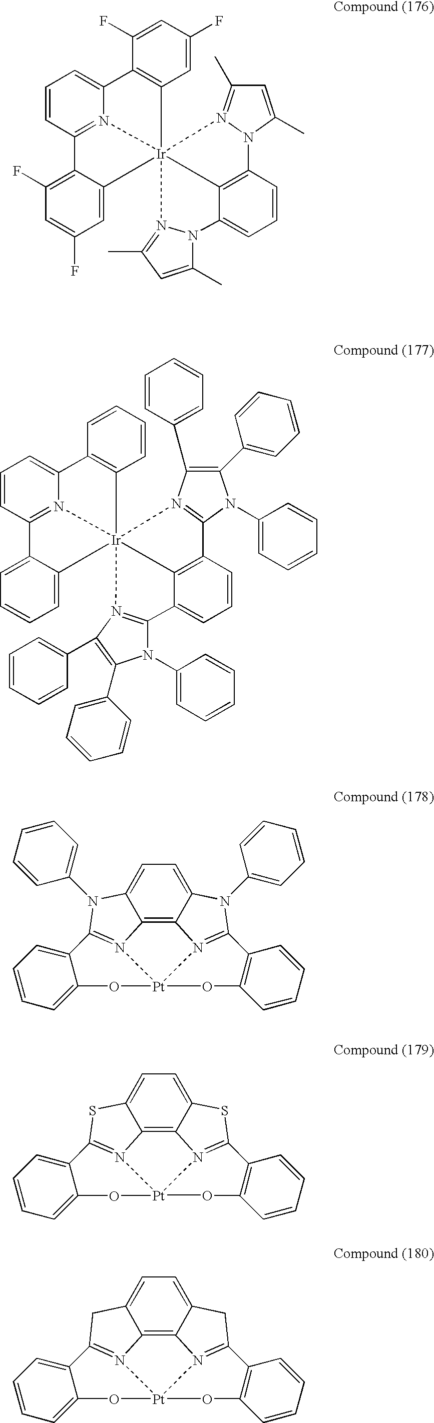

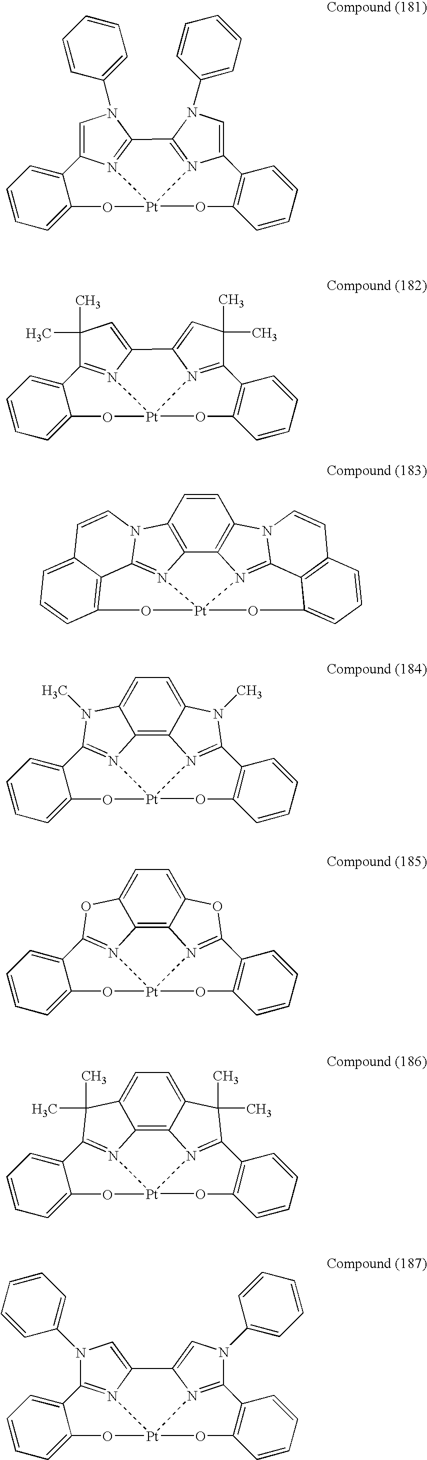

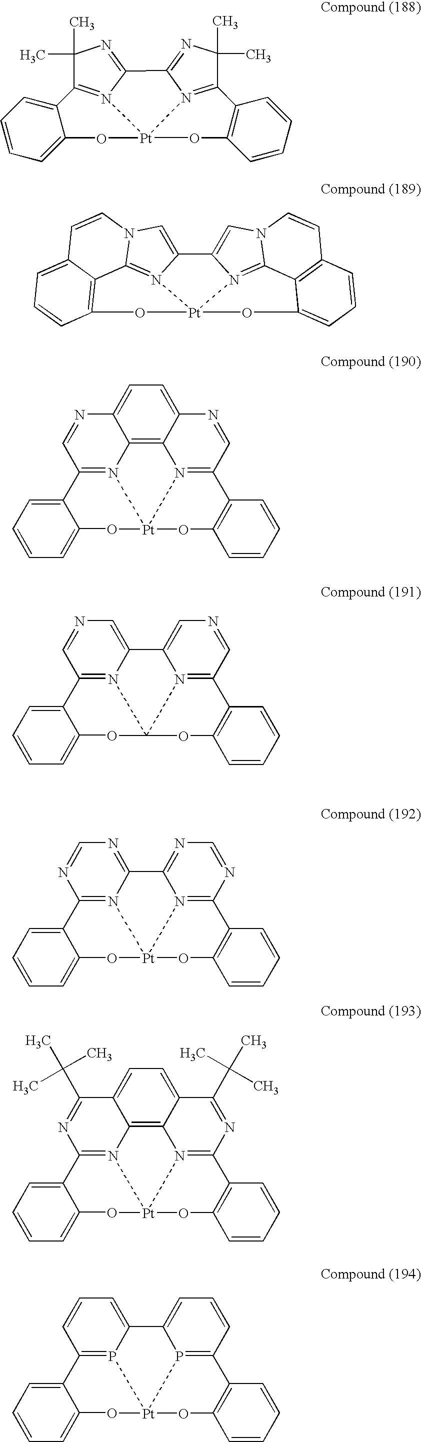

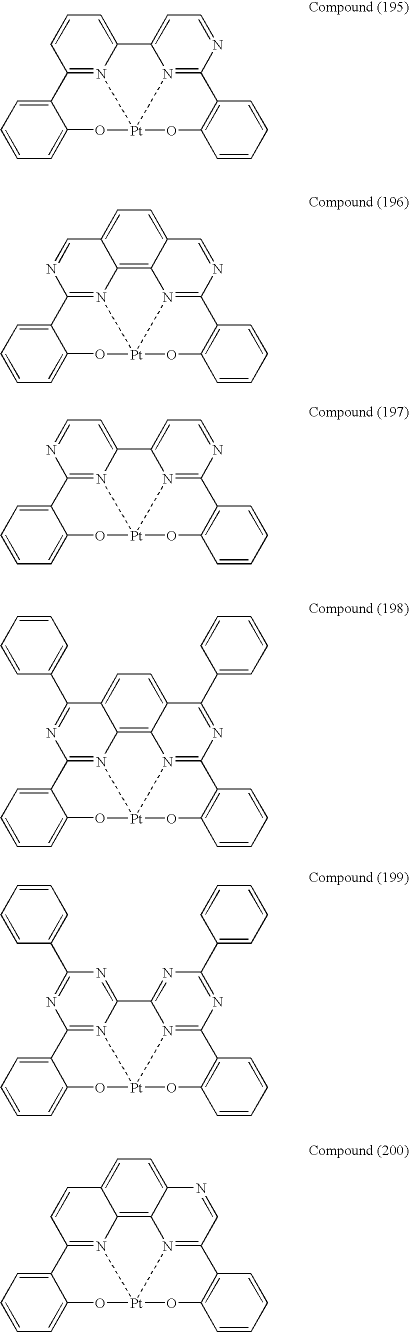

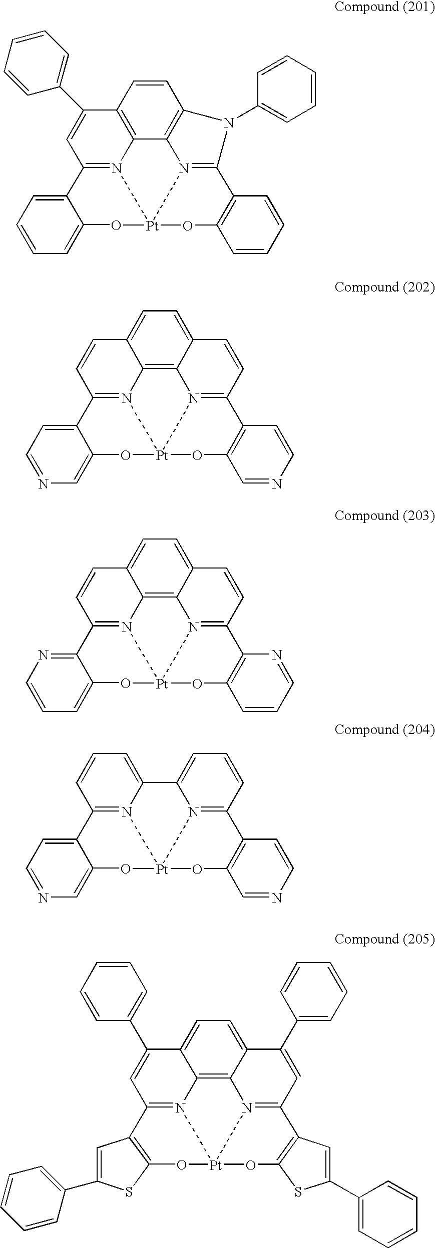

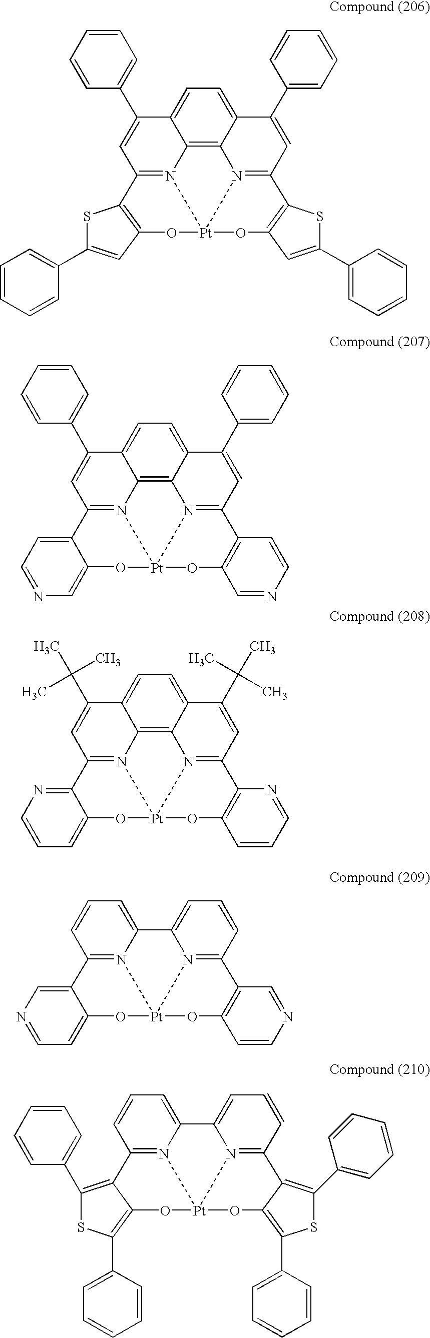

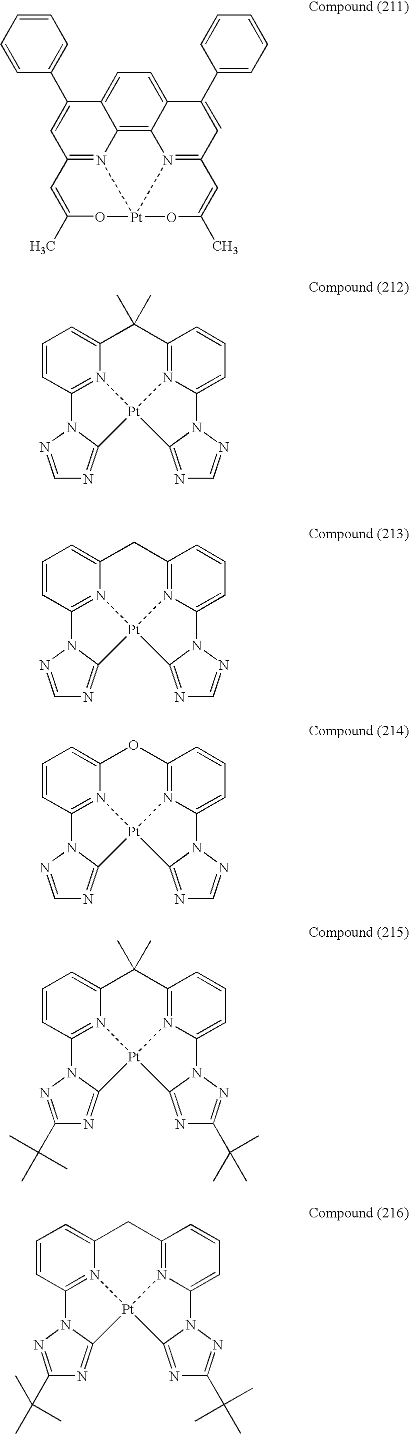

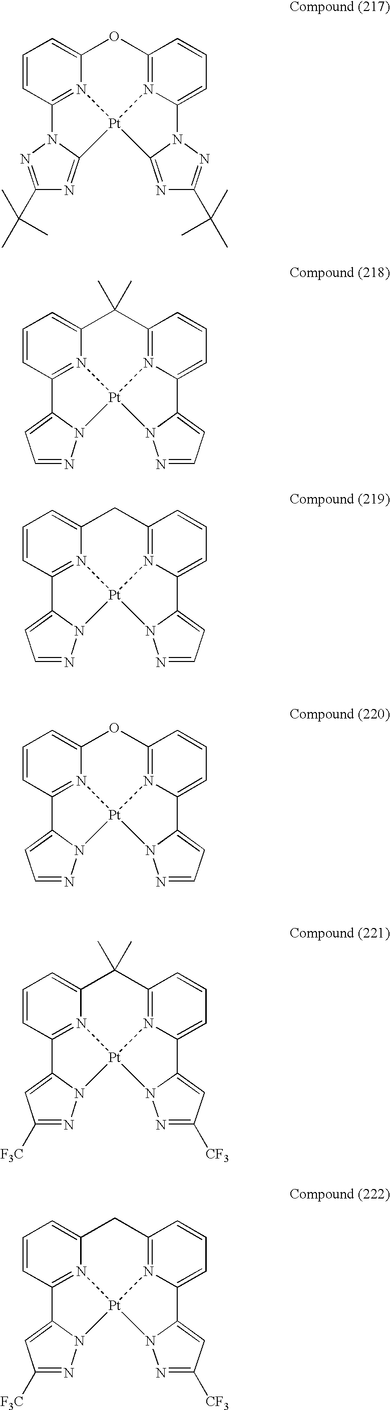

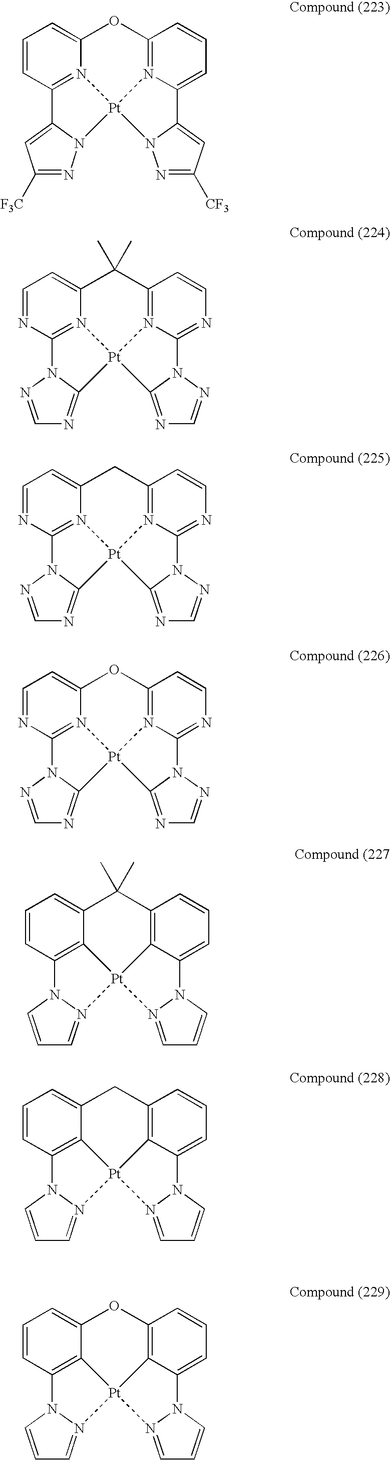

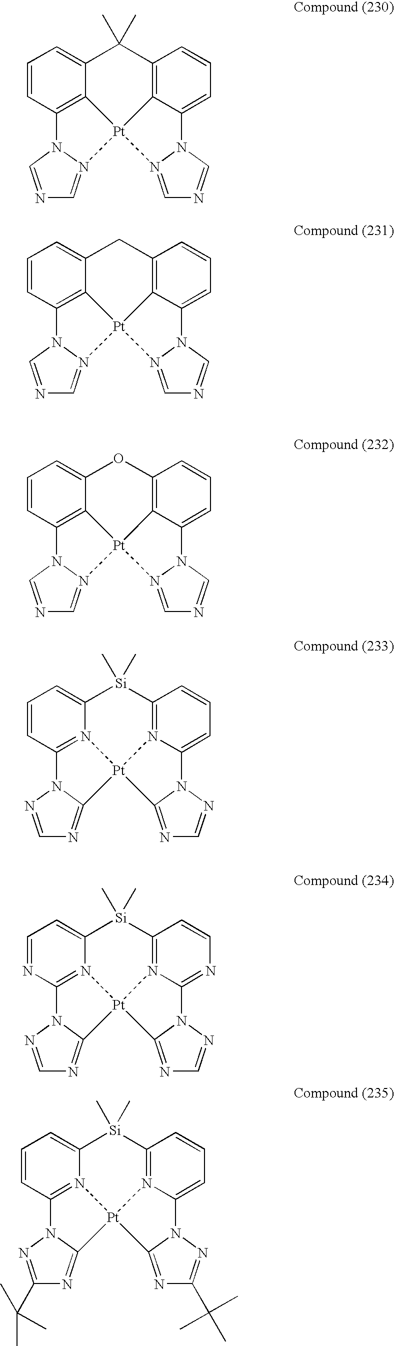

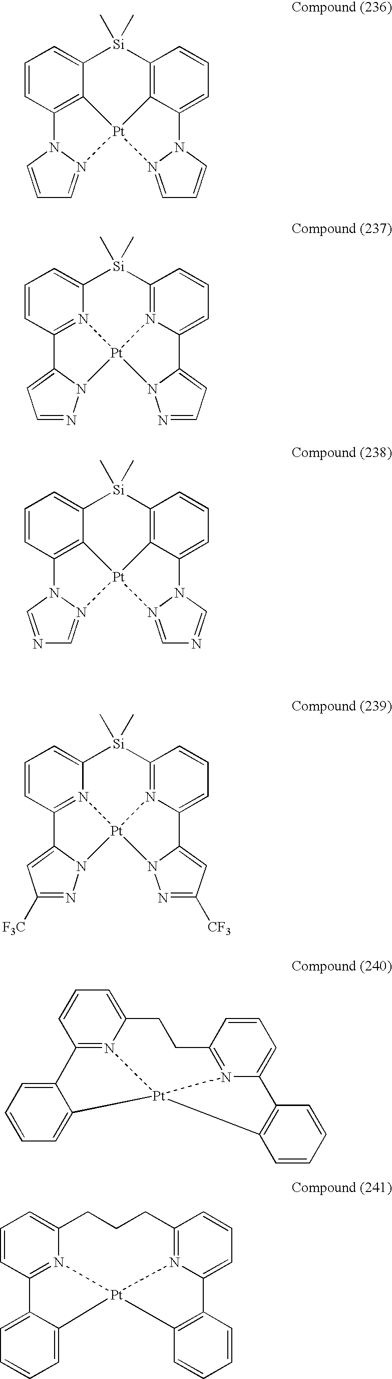

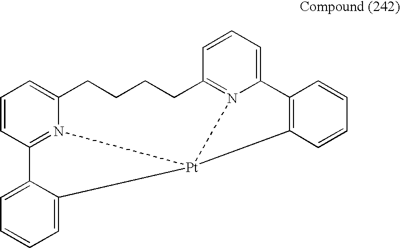

The luminescent device of the present invention is a device that has a luminescent layer (hereinafter also referred to as a light-emitting layer) or a plurality of organic-compound layers including a luminescent layer, formed between a pair of electrodes of an anode and a cathode, and that may have a hole-injecting layer, a hole-transporting layer, an electron-injecting layer, an electron-transporting layer, and a protective layer, etc. in addition to the luminescent layer. Each of these layers may each have additional function(s). Each of these layers may be formed of different types of materials.

Next, elements constituting the luminescent device of the present invention are described in detail.

<Substrate>

The substrate that can be used in the present invention is preferably a substrate that does not scatter or attenuate the light emitted from the organic-compound layer. Examples thereof include inorganic materials such as zirconia-stabilized yttrium (YSZ) and glass; and organic materials such as polyesters (for example, polyethylene terephthalate, polybutylene terephthalate, and polyethylene naphthalate), polystyrenes, polycarbonates, polyethersulfones, polyarylates, polyimides, polycycloolefins, norbornene resins, and poly(chlorotrifluoroethylene).

For example, when glass is used as a substrate, alkali-free glass may be preferably used in order to lessen amount of ions eluted from glass. When soda lime glass is used as a substrate, it is preferable to use soda lime glass coated with a barrier coat such as silica. When an organic material is used, it is preferable to use an organic material excellent in heat resistance, dimensional stability, solvent resistance, electrical insulating properties, and workability.

Shape, structure, and size of the substrate are not particularly limited, and may be appropriately selected according to uses and purposes of use of the light-emitting device. The substrate is generally in a plate form. The substrate can be a single-layer structure or a laminated-structure. Further the substrate can be formed of a single member or a combination of two or more members.

The substrate may be colorless and transparent, or colored and transparent. The substrate is preferably colorless and transparent, since it does not scatter or attenuate the light emitted from the organic light-emitting layer.

A moisture-permeation-preventing layer (gas barrier layer) can be provided on the front surface and back surface of the substrate.

The material of the moisture-permeation-preventing layer (gas barrier layer) is preferably an inorganic substance, such as silicon nitride, silicon oxide, or the like, and the moisture-permeation-preventing layer (gas barrier layer) may be formed by, for example, a high-frequency sputtering method.

Further, when a thermoplastic substrate is used, a hardcoat layer, an undercoat layer, and the like may be provided on the substrate, if necessary.

<Anode>

Usually, an anode functions as an electrode to supply holes to the organic-compound layer. As long as the anode has such a function, the shape, structure, and size of the anode are not particularly limited, and may be appropriately selected from those in known electrode material, according to uses and purposes of use of the light-emitting device. As described above, the anode is generally provided as a transparent anode.

Examples of the material of the anode include simple metals, alloys, metal oxides, electric conductive compounds, and mixtures thereof, and materials having a work function of 4.0 eV or more are preferred. Specific examples of the material for the anode include: tin oxides doped with antimony (ATO) or with fluorine (FTO) or the like; conductive metal oxides such as tin oxide, zinc oxide, indium oxide, indium tin oxide (ITO), and indium zinc oxide (IZO); metals such as gold, silver, chromium, and nickel; mixtures or laminates of any of the above-mentioned metals and the conductive metal oxides; inorganic conductive substances such as copper iodide and copper sulfide; organic conductive materials such as polyaniline, polythiophene, and polypyrrole; laminates of any of these materials and ITO; and the like. Among these, conductive metal oxides are preferred, and ITO is particularly preferred from the view point of productivity, high conductivity, transparency, and the like.

The anode can be formed on the substrate by a method which is appropriately selected, dependently on the material of the anode, from wet methods such as printing methods and coating methods; physical methods such as vacuum vapor deposition methods, sputtering methods, and ion plating methods; and chemical methods such as chemical vapor deposition (CVD) methods and plasma CVD methods. For example, when ITO is selected as the material of the anode, the anode can be formed by a direct current or high-frequency sputtering method, a vacuum vapor deposition method, an ion plating method, or the like.

In the organic electroluminescent device of the present invention, the position where the anode is formed is not particularly limited, and can be appropriately selected according to the use or purpose of the light-emitting device. Preferably, the anode is formed on a surface of the substrate. In this case, the anode may be formed on the whole surface of one side of the substrate, or formed on a part thereof.

At the time of formation of the anode, the anode can be patterned by chemical etching methods such as photolithography, physical etching methods using a laser or the like, vacuum vapor deposition or sputtering methods using a mask, lift-off methods, printing methods and the like.

The thickness of the anode is not specifically limited, but selected depending upon a material constituting the anode, and may be usually 10 nm to 50 μm, and preferably 50 nm to 20 μm.

The resistance value of the anode is preferably 10³ Ω/□ or less, preferably 10² Ω/□ or less. When the anode is transparent, the anode may be colorless and transparent, or colored and transparent. In order to take out light from the transparent anode side, the transmittance thereof is preferably set to 60% or more, and more preferably set to 70% or more.

Transparent anodes are described in detail in “Tomei-Denkyokumaku no Shintenkai (New Development of Transparent Electrode Films)” (supervised by Yutaka Sawada, and published by CMC, 1999) and the disclosures can be applied to the present invention. In particular, in the case of using a plastic substrate having a low heat resistance, it is preferable to form a transparent anode using ITO or IZO and forming into a film at a low temperature of 150° C. or less.

<Cathode>

The cathode generally functions as an electrode to supply electrons to the organic-compound layer. As long as the cathode has such a function, the shape, structure, and size of the cathode are not particularly limited, and may be appropriately selected, according to uses and purposes of use of the light-emitting device, from those of known electrode materials.

As the materials used to form the cathode, simple metals, alloys, metal oxides, electric conductive compounds, or mixtures thereof may be used. Preferably, a material having a work function of 4.5 eV or less is used. Examples of the material used to form the cathode include: alkali metals (such as Li, Na, K, and Cs); alkaline earth metals (such as Mg and Ca); gold, silver, lead, aluminum, a sodium-potassium alloy, a lithium-aluminum alloy, a magnesium-silver alloy, indium, rare earth metals (such as ytterbium), and the like. These materials may be used singly. However, they are preferably used in combination of two or more thereof, in view of obtaining stability and electron-injecting properties compatibly.

Of these materials, alkali metals and alkali earth metals are preferred as the material used to form the cathode, from the standpoint of electron-injecting properties. From the standpoint of storage stability, a material mainly composed of aluminum is preferred.

Herein, the term “material mainly composed of aluminum” means simple substance of aluminum, and alloys or mixtures comprising-aluminum and 0.01 to 10 mass % of alkali metal or alkaline earth metal (e.g. a lithium-aluminum alloy, a magnesium-aluminum alloy, and the like).

Materials for the cathode are-described in JP-A-2-15595 and JP-A-5-121172 in detail, and the materials described in these publications are applicable for the present invention.

A method of forming the cathode is not specifically limited, but the forming of the cathode can be carried out according to a known method. That is to say, the cathode can be formed by a method selected from wet methods such as printing methods and coating methods; physical methods such as vacuum deposition methods, sputtering methods, and ion plating methods; and chemical methods such as CVD methods, plasma CVD methods, taking suitability to the above-described materials used to form the cathode into consideration. For example, in the case of selecting a metal(s) as a material for the cathode, the cathode can be formed by depositing one or two or more kinds of metals simultaneously or sequentially by a sputtering method, or the like.

At the time of formation of the cathode, patterning of the cathode may be conducted by a chemical etching method such as photolithography; a physical etching method using laser, a vacuum vapor deposition method or sputtering method using a mask, a lift-off method or a printing method.

In the present invention, the position to which the cathode is formed is not specifically limited, but it may be formed on the whole or on a part of the surface of the organic-compound layer.

A dielectric layer made of a fluoride or oxide of an alkali metal or alkali earth metal or some other material may be inserted between the cathode and the organic-compound layer, to have a thickness of 0.1 nm to 5 nm. The dielectric layer may be regarded as a kind of an electron-injecting layer. The dielectric layer may be formed, for example, by a vacuum vapor deposition method, a sputtering method, an ion plating method, or the like.

The thickness of the cathode may be appropriately selected according to the material forming the cathode, and is usually from 10 nm to 5 μm, preferably from 50 nm to 1 μm.

The cathode may be transparent or opaque. The transparent cathode can be formed by filming any one of the above-mentioned materials into a thin layer having a thickness of 1 nm to 10 nm, and then laminating a transparent conductive material such as ITO or IZO thereon.

<Organic-compound Layer>

The organic-compound layer in the present invention will be explained.

The organic electroluminescent device of the present invention comprises at least one organic-compound layer, which includes an organic luminescent layer. As organic-compound layers other than the organic luminescent layer, as described above, a hole-transporting layer, an electron-transporting layer, a charge protecting layer, a hole-injecting layer, an electron-injecting layer, and the like can be mentioned.

—Formation of an Organic-compound Layer—

A method of forming each of layers constituting organic-compound layer(s) of the organic electroluminescent device of the present invention is not specifically limited. As the method, various methods, such as a resistance heating vapor deposition method, an electron-beam method, a sputtering method, a molecular lamination method, a coating method (e.g., a spray coating method, dip coating method, dipping method, roll coating method, gravure coating method, reverse coating method, roll brushing method, air knife coating method, curtain coating method, spin coating method, flow coating method, bar coating method, micro gravure coating method, air doctor coating method, blade coating method, squeeze coating method, transfer roll coating method, kiss coating method, cast coating method, extrusion coating method, wire bar coating method, and screen coating method), an inkjet method, a printing method, and a transfer method, can be adopted.

—Organic Luminescent Layer—

The organic luminescent layer is a layer having a function of emission, upon application of electric field, in which it receives a hole from the anode, the hole injecting layer, or the hole-transporting layer and it receives an electron from the cathode, the electron-injecting layer, or the electron-transporting layer, and it provides a field where the hole and the electron are re-combined.

The luminescent layer in the present invention comprises a host material and two or more luminescent materials (dopant materials). As the host material, preferred is an electron-transporting material.

At least one of the luminescent materials contained in the luminescent layer is a metal complex having a tridentate or higher polydentate chain ligand. The concrete structure thereof is as described above.

As the host material for the luminescent layer, preferred are an amine compound (for example, a triarylamine compound), a metallic chelate oxinoide compound (i.e. a compound having a metal-oxygen bond; the metal is aluminum, zinc, or a transition metal, and the ligand is a 8-hydroxyquinoline derivative, a 2-(2-pyridino) phenol derivative, or the like), a polyarylene compound (e.g. hexaphenylbenzene derivatives, and the like), a condensate aromatic hydrocarbon-ring compound, and a non-complex, aromatic, nitrogen-containing heterocyclic compound (e.g. carbazole compound derivatives, and the like). The host material may be a mixture of two or more different types of compounds.

It is preferable that T1 (the energy level of minimum multiplet term excited state) of the host material is larger than T1 level of a dopant material. By co-depositing a host material and a dopant material, a luminescent layer in which the host material is doped with the dopant material may be preferably formed.

The film thickness of the luminescent layer is not particularly restricted, but it is generally preferably from 1 nm to 500 nm, more preferably from 5 nm to 200 nm, and still more preferably from 10 nm to 100 nm.

—Hole-injecting Layer and Hole-transporting Layer—

A hole-injecting layer and a hole-transporting layer are layers each having a function of receiving a hole from the anode or a layer at the anode side, to transport it to a layer at the cathode side. Specifically, the hole-injecting layer and the hole-transporting layer each are preferably a layer containing carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidyne-series compounds, porphyrin-series compounds, organic silane derivatives, carbon, phthalocyanine derivatives, metallophthalocyanines, and the like.

The film thickness of the hole-injecting layer is not particularly limited, and in general, it is preferably from 1 nm to 500 nm, more preferably from 5 nm to 200 nm, and further preferably from 10 nm to 100 nm. The film thickness of the hole-transporting layer is not particularly limited, and in general, it is preferably from 1 nm to 500 nm, more preferably from 5 nm to 200 nm, and further preferably from 10 nm to 100 nm. The hole-injecting layer or hole-transporting layer may have a single-layer structure of one kind or two or more kinds of the above materials, or alternatively, a multilayer structure comprising plural layers having the same composition or different compositions.

—Electron-injecting Layer and Electron-transporting Layer—

An electron-injecting layer and an electron-transporting layer are layers each having a function of receiving an electron from the cathode or a layer at the cathode side, to transport it to a layer at the anode side. As the materials for the electron-injecting layer and electron-transporting layer, metal chelate oxynoid compounds, polyarylene compounds, condensed aromatic carbocyclic compounds, and non-complex aromatic heterocyclic compounds are preferable. Specific examples of the materials include triazole derivatives, oxazole derivatives, oxadiazole derivatives, imidazole derivatives, fluorenone derivatives, anthraquinodimethane derivatives, anthrone derivatives, diphenylquinone derivatives, thiopyrandioxide derivatives, carbodiimide derivatives, fluorenylidenemethane derivatives, distyrylpyrazine derivatives, tetracarboxylic acid anhydrides of aromatic rings such as naphthalene and perylene, phthalocyanine derivatives, various metal complexes represented by metal complexes of 8-quinolinol derivatives, metallophthalocyanines, and metal complexes having benzoxazole or benzothiazole ligands; organosilane compounds, derivatives thereof.

The film thickness of the electron-injecting layer and the electron-transporting layer is not particularly restricted, but it is generally preferably from 1 nm to 500 nm, more preferably from 5 nm to 200 nm, and still more preferably from 10 nm to 100 nm, respectively. The electron-injecting layer and the electron-transporting layer may have a single-layer structure comprising one or two or more of the above materials, or may have a multilayer structure comprising a plurality of layers of the same composition or different compositions.

<Hole-blocking Layer>

A hole-blocking layer may be disposed between a luminescent layer and an electron-transporting layer to block holes from leaving the luminescent layer in the direction of the electron-transporting layer. Blocking layers may also be used to block excitons from diffusing out of the luminescent layer. The theory and use of blocking layers is described in more detail in U.S. Pat. No. 6,097,147 and United States Patent Application Publication No. 2003/0230980, which are incorporated by reference in their entireties.

A hole-blocking layer has a function that prevents holes transported from the anode to luminescent layer from passing through the cathode side. In this invention, a hole-blocking layer may be provided as an organic layer that is adjacent to the cathode-side of the luminescent layer.

Examples of an organic compound that forms a hole-blocking layer include an aluminum complex such as BAlq; a triazole derivative, and a phenanthroline derivative such as BCP.

The thickness of a hole-blocking layer is preferably 1 nm to 500 nm, more preferably 5 nm to 200 nm, and further preferably, 10 nm to 100 nm.

A hole-blocking layer may have a single-layer structure of one kind or two or more kinds of the above-mentioned materials, or alternatively, a multilayer structure comprising plural layers having the sane composition or different compositions.

<Protective Layer>

In the present invention, the whole organic electroluminescent device may be protected by a protective layer.

Materials contained in the protective layer may be any material as long as they have a function of preventing substances which accelerate deterioration of the device, such as water or oxygen, from entering the device.

Specific examples of the materials include metals such as In, Sn, Pb, Au, Cu, Ag, Al, Ti, and Ni; metal oxides such as MgO, SiO, SiO², Al₂O₃, GeO, NiO, CaO, BaO, Fe₂O₃, Y₂O₃, and TiO₂; metal nitrides such as SiN_{X} and SiN_{X}O_{y}; metal fluorides such as MgF₂, LiF, AlF₃, and CaF₂; polyethylene, polypropylene, polymethyl methacrylate, polyimide, polyurea, polytetrafluoroethylene, polychlorotrifluoroethylene, polydichlorodifluoroethylene, copolymers of chlorotrifluoroethylene and dichlorodifluoroethylene, copolymers prepared by copolymerizing a monomer mixture of tetrafluoroethylene and at least one comonomer; fluorine-containing copolymers having cyclic structures on the main chain, water-absorbing substances having a water absorption rate of at least 1%, and moisture-proof substances having a water absorption rate of at most 0.1%.

The forming process of the protective layer is also not particularly restricted, and, for example, a vacuum deposition process, a sputtering process, a reactive sputtering process, an MBE (molecular beam epitaxy) process, a cluster ion beam process, an ion-plating process, a plasma polymerization process (a high frequency exciting ion-plating process), a plasma CVD (chemical vapor deposition) process, a laser CVD process, a heat CVD process, a gas source CVD process, a coating process, a printing process, and a transfer process can be applied.

<Sealing>

The entire organic electroluminescent device of the present invention may be sealed by a sealing container.

It is allowable to fill the space between the sealing container and the light-emitting device with a moisture absorbent or an inert liquid. The kind of the moisture absorbent is not particularly limited. Examples thereof include barium oxide, sodium oxide, potassium oxide, calcium oxide, sodium sulfate, calcium sulfate, magnesium sulfate, phosphorus pentaoxide, calcium chloride, magnesium chloride, copper chloride, cesium fluoride, niobium fluoride, calcium bromide, vanadium bromide, molecular sieves, zeolite, and magnesium oxide. The kind of the inert liquid is not limited. Examples thereof include paraffins, liquid paraffins, fluorine-series solvents (such as perfluoroalkanes, perfluoroamines, and perfluoroethers), chlorine-series solvents, and silicone oils.

The organic electroluminescent device of the present invention can be caused to emit light by applying a direct-current (which may include alternating-current component) voltage (usually from 2 to 15V), or a direct current between the anode and the cathode.

For the driving of the light-emitting device of the present invention, methods described in the following can be utilized: JP-A-2-148687, JP-A-6-301355, JP-A-5-29080, JP-A-7-134558, JP-A-8-234685 and JP-A-8-241047; Japanese Patent No. 2784615; U.S. Pat. No. 5,828,429, and U.S. Pat. No. 6,023,308, and the like.

The organic electroluminescent device of the present invention has high external quantum efficiency, high color purity, and excellent durability.

The organic electroluminescent device of the present invention has high external quantum efficiency, high color purity, and excellent durability, and further it has excellent luminescent properties. The luminescent device of the present invention can be preferably used in such fields as display devices, displays, backlights, electrophotography, illumination light sources, recording light sources, exposure light sources, reading light sources, signs, signboards, interiors, and optical communications.

The present invention will be described in more detail based on examples given below, but the invention is not meant to be limited by these.

### EXAMPLES

### Experiment 1

### Example 1

A glass-substrate on which 150-nm thickness indium-tin oxide (ITO) transparent conductive film was deposited (commercially available from Geomatic Co., Ltd.) was subjected to patterning by using photolithography and hydrochloric acid etching, thereby an anode was formed. The pattern-formed ITO substrate was subjected to ultrasonic washing with acetone, water-washing with pure water, and ultrasonic washing with isopropyl alcohol, in that order. Then, the pattern-formed ITO substrate was dried with nitrogen blow, cleaned with UV light ozone washing, and placed in a vacuum evaporation apparatus. Thereafter, the vacuum evaporation apparatus was evacuated until the degree of vacuum in the vacuum evaporation apparatus was 2.7×10⁻⁴ Pa or below.

Subsequently, copper phthalocyanin (CuPc) illustrated below was heated in the above-described vacuum evaporation apparatus and evaporated at evaporation speed of 0.1 nm/sec, to form a hole-injecting layer having a film thickness of 10 nm.

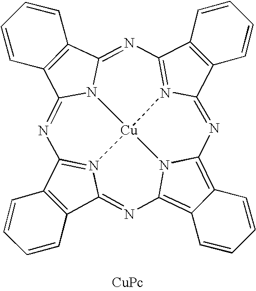

Next, 4,4′-bis[N-(1-naphthyl)-N-phenylamino]biphenyl (α-NPD) illustrated below was heated by a heater and evaporated at an evaporation speed of 0.2 nm/sec, to form a hole-transporting layer having a film thickness of 30 nm.

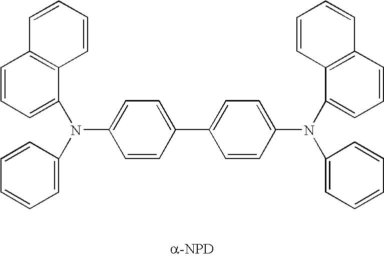

Subsequently, 4,4′-N,N′-dicarbazole-biphenyl (CBP) illustrated below, as a host material in a luminescent layer; tris(2-phenylpyridine) iridium (Dopant A) illustrated below and Compound (1) illustrated below, as phosphorescent organic metal complexes for dopant materials were heated and evaporated, to form a luminescent layer, by a ternary simultaneous evaporation method, on the hole-transporting layer formed in the above manner. The evaporation speed of CBP was controlled to be 0.2 nm/sec, and thus a luminescent layer comprising 5 mass % of Dopant A and 5 mass % of Compound (1) and having a film thickness of 30 nm was laminated on the hole-transporting layer.

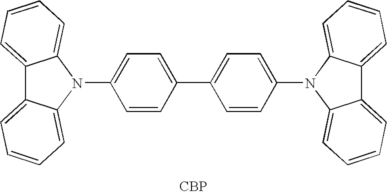

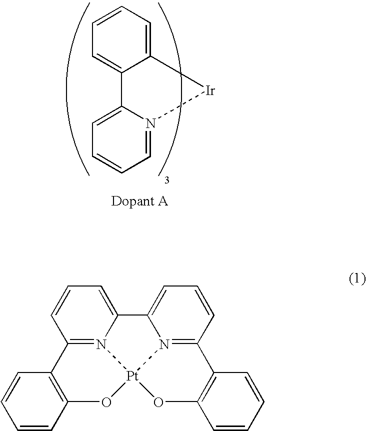

Further, on the luminescent layer, Compound (BAlq) illustrated below was evaporated at an evaporation speed of 0.1 nm/sec, to laminate a hole-blocking layer having a film thickness of 10 nm.

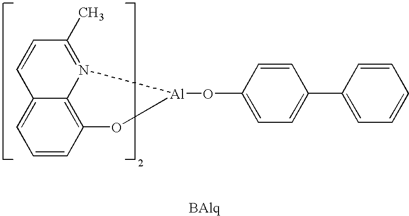

Subsequently, on the hole-blocking layer, tris(8-hydroxyquinolinate) aluminum (Alq) illustrated below was evaporated at an evaporation speed of 0.2 nm/sec, to form an electron-transporting layer having a film thickness of 40 nm.

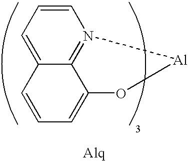

Thereafter, on the electron-transporting layer, lithium fluoride (LiF) was evaporated at an evaporation speed of 0.1 nm/sec, to form a film having a thickness of 1.5 nm, as an electron-injecting layer. Then, aluminum was evaporated at an evaporation speed of 0.5 nm/sec, to form a cathode having a film thickness of 200 nm.

In the above, in order to obtain a desired film thickness, evaporation was monitored with a quartz oscillator-type film-formation controller (CRTM6000 (trade name) manufactured by ULVAC CORP).

Next, aluminum-made lead wires were connected to the anode and the cathode, respectively.

Without exposing the thus-obtained device to air, the device was put into a glove box, the atmosphere in which was replaced with nitrogen gas in advance. In the glove box, 10 mg of calcium oxide powder, as a water-capturing agent, was put into a stainless-steel sealing cover inside of which was formed a recess, and then fixed by an adhesive tape. Sealing process was completed by fixing the sealing cover with UV light curable-type adhesive (XNR5516HV (trade name), manufactured by NAGASE-CIBA).

In the manner as described above, an organic electroluminescent device of Example 1 was obtained.

Direct-current voltage was applied to the thus-obtained organic electroluminescent device with Source-Measure Unit 2400 (trade name) manufactured by Keithley Corp., and luminance was measured with BM-8 (trade name) manufactured by Topcon Corporation.

The spectral waveform was measured with a multichannel analyzer PMA-11 (trade name) manufactured by Hamamatsu Photonics K.K.

From the result of these measurements, the external quantum efficiency at 300 cd/m² and the peak value of emission wavelength were obtained.

The maximum wavelength of emission spectrum of the device of Example 1 was 620 nm. The peak value of emission spectrum (hereinafter referred to as “PL spectrum”) obtained when Compound (1) was irradiated with UV light was 616 nm, and this value was nearest to the maximum wavelength of emission spectrum, among the organic compounds used in Example 1. Therefore, the emission spectrum of the device of Example 1 was confirmed that it was derived from Compound (1).

Further, constant current driving was carried out at the initial luminance of 300 cd/m², and the time required until luminance became 150 cd/m² was measured. This time value was regarded as an index of durability. (Shown as “half-life period” in Table 1.)

### Example 2

An organic electroluminescent device was prepared in the same manner as Example 1, except that Compound (1) used in Example 1 was replaced with Compound (15). The thus-obtained device was subjected to the same measurements to Example 1.

The maximum wavelength of emission spectrum of the device of Example 2 was 590 nm. Since the peak value of PL spectrum of Compound (15) was 586 nm, the emission spectrum of the device of Example 2 was confirmed that it was derived from Compound (15).

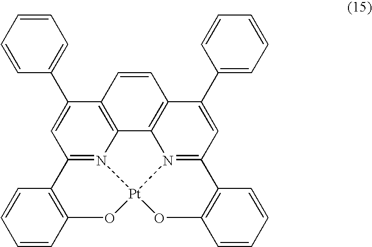

### Example 3

An organic electroluminescent device was prepared in the same manner as Example 1, except that Compound (1) used in Example 1 was replaced with Compound (88). The thus-obtained device was subjected to the same measurements to Example 1.

The maximum wavelength of emission spectrum of the device of Example 3 was 630 nm. Since the peak value of PL spectrum of Compound (88) was 620 nim, the emission spectrum of the device of Example 3 was confirmed that it was derived from the Compound (88).

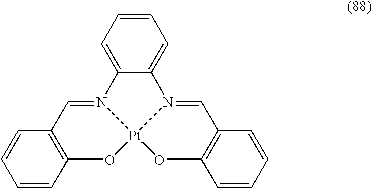

### Example 4

An organic electroluminescent device was prepared in the same manner as Example 1, except that Compound (1) used in Example 1 was replaced with Compound (88) and the concentration of Compound (88) was changed to 10 mass %. The thus-obtained device was subjected to the same measurements to Example 1.

The maximum wavelength of emission spectrum of the device of Example 4 was 630 nm. The emission spectrum of the device of Example 4 was confirmed that it was derived from Compound (88).

### Example 5

An organic electroluminescent device was prepared in the same manner as Example 1, except that Dopant A used in Example 1 was replaced with Compound (83) and Compound (1) used in Example 1 was replaced with Compound (15). The thus-obtained device was subjected to the same measurements to Example 1.

The maximum wavelength of emission spectrum of the device of Example 5 was 595 nm. The emission spectrum of the device of Example 5 was confirmed that it was derived from Compound (15).

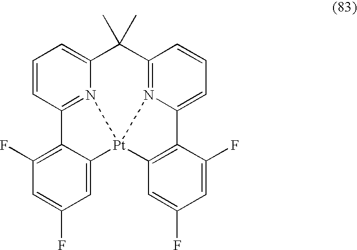

### Comparative Example 1

An organic electroluminescent device was prepared in the same manner as Example 1, except that only Compound (1) was used as a dopant contained in the luminescent layer. The thus-obtained device was subjected to the same measurements to Example 1.

The maximum wavelength of emission spectrum of the device of Comparative example 1 was 620 nm, and the emission spectrum of the device was confirmed that it was derived from Compound (1). Another peak was observed at 500 nm.

### Comparative Example 2

An organic electroluminescent device was prepared in the same manner as Example 1, except that only Compound (15) was used as a dopant contained in the luminescent layer. The thus-obtained device was subjected to the same measurements to Example 1.

The maximum wavelength of emission spectrum of the device of Comparative example 2 was 595 nm, and the emission spectrum of the device was confirmed that it was derived from Compound (15). Another peak was observed at 500 nm.

### Comparative Example 3

An organic electroluminescent device was prepared in the same manner as Example 1, except that only Compound (88) was used as a dopant contained in the luminescent layer. The thus-obtained device was subjected to the same measurements to Example 1.

The maximum wavelength of emission spectrum of the device of Comparative example 3 was 630 nm, and the emission spectrum of the device was confirmed that it was derived from Compound (88). Another peak was observed at 500 nm.

Results of the measurements of the devices of Examples 1 to 5 and Comparative examples 1 to 3 are shown in Table 1.

TABLE 1

| | Dopant | External | | |
|---|---|---|---|---|
| | in | quantum | Peak | Half-life |
| | luminescent | efficiency | wavelength | period |
| | layer | (%) | (nm) | (hr) |
| Example 1 | (1), A | 4.5 | 620 | 1,500 |
| Example 2 | (15), A | 6.3 | 595 | 3,300 |
| Example 3 | (88), A | 4.8 | 630 | 3,500 |
| Example 4 | (88), A | 5.1 | 630 | 3,700 |
| Example 5 | (15), (83) | 5.3 | 595 | 3,000 |
| Comparative | (1) | 1.6 | 620, 500 | 850 |
| example 1 | | | | |
| Comparative | (15) | 3.9 | 595, 500 | 1,500 |
| example 2 | | | | |
| Comparative | (88) | 2.2 | 630, 500 | 1,300 |
| example 3 | | | | |

In each of Comparative examples 1 to 3, an emission peak at 500 nm was observed. Since it is BAlq that has PL spectrum nearest to the 500 nm, among the organic compounds used in the luminescent layer and the layers adjacent to the luminescent layer, it is considered that the emission peak of each of Comparative examples 1 to 3 was derived from BAlq. Contrary, any emission peak at 500 nm was not observed in Examples 1 to 5, and color purity, external quantum efficiency, and durability were improved.

Similarly, when other compounds according to the present invention are used, it is possible to prepare organic electroluminescent devices having improved external quantum efficiency, improved color purity, and improved durability. Such effects of the present invention are observed not only in the range from orange color to red color, but also in another luminous color.

### Experiment 2

Next, in order to check the durability at high temperature, devices were prepared in Examples and Comparative examples as described below in addition to the device prepared in Example 1.

### Example 6

An organic electroluminescent device was prepared in the same manner as Example 1, except that Compound (1) used in Example 1 was replaced with Compound (66) and Dopant A used in Example 1 was replaced with Dopant B.

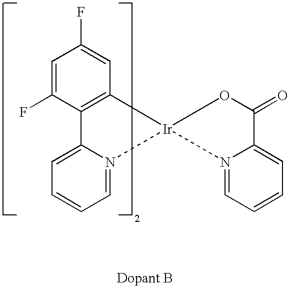

### Example 7

An organic electroluminescent device was prepared in the same manner as Example 1, except that Compound (1) used in Example 1 was replaced with Compound (79) and Dopant A used in Example 1 was replaced with Dopant B.

### Example 8

An organic electroluminescent device was prepared in the same manner as Example 1, except that Compound (1) used in Example 1 was replaced with Compound (100).

### Example 9

An organic electroluminescent device was prepared in the same manner as Example 1, except that Compound (1) used in Example 1 was replaced with Compound (143) and Dopant A used in Example 1 was replaced with Dopant B.

### Comparative Example 4

An organic electroluminescent device was prepared in the same manner as Example 1, except that Compound (1) used in Example 1 was replaced with platinum porphyrin (PtOEP).

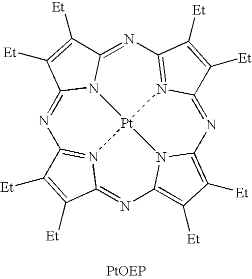

### Comparative Example 5

An organic electroluminescent device was prepared in the same mner as Example 1, except that only Compound (66) was used as a dopant contained in the luminescent layer.

### Comparative Example 6

An organic electroluminescent device was prepared in the same manner as Example 1, except that only Compound (79) was used as a dopant contained in the luminescent layer.

### Comparative Example 7

An organic electroluminescent device was prepared in the same manner as Example 1, except that only Compound (100) was used as a dopant contained in the luminescent layer.

### Comparative Example 8

An organic electroluminescent device was prepared in the same manner as Example 1, except that only Compound (143) was used as a dopant contained in the luminescent layer.

For each of the organic electroluminescent devices, luminance and spectrum at current density of 10 mA/cm² were measured. Then, the devices were preserved in such an environment that temperature was 80° C. and relative humidity was 95%. After elapse of 50 hours, these devices were taken out from the environment, and luminance and spectrum at current density of 10 mA/cm² were measured.

With respect to luminance, values of luminance of the respective devices after preservation were expressed in relative values to the values of luminance before preservation, taking the values before preservation as 100. By comparing spectrum measured before preservation with that measured after preservation, shift of the value of peak wavelength was examined.

Results obtained by these experiments are as shown in Table 2.

TABLE 2

| | Luminance | Spectrum |
|---|---|---|
| Example 1 | ◯ | ◯ |
| Example 2 | ◯ | ◯ |
| Example 3 | ◯ | ◯ |
| Example 6 | ◯ | ◯ |
| Example 7 | ◯ | ◯ |
| Example 8 | ◯ | ◯ |
| Example 9 | ◯ | ◯ |
| Comparative example 1 | Δ | X |
| Comparative example 2 | Δ | Δ |
| Comparative example 3 | Δ | X |
| Comparative example 4 | Δ | X |
| Comparative example 5 | Δ | Δ |
| Comparative example 6 | Δ | Δ |
| Comparative example 7 | Δ | X |
| Comparative example 8 | Δ | Δ |

In Table 2:

With respect to “luminance”: ◯ means 100 to 90; Δ means 90 to 70; × means 70 or below.

With respect to “spectrum”: ◯ means that shift of the peak wavelength is less than 3 nm; Δ means that shift of the peak wavelength is 3 mm or more but less than 5 nm; × means that shift of the peak wavelength is 5 run or more.

As evident from Table 2, the devices of Examples 1 to 9, each having the structure according to the present invention, were improved in preservation durability at high temperature. However, as in the case of Comparative example 4, even if the device had a similar structure to the present invention, satisfactory preservation durability at high temperature cannot be obtained when a material used as a luminescent material is different from the metal complex defined in the present invention.

Having described our invention as related to the present embodiments, it is our intention that the invention not be limited by any of the details of the description, unless otherwise specified, but rather be construed broadly within its spirit and scope as set out in the accompanying claims.

What we claim is:

1. An organic electroluminescent device comprising an anode, a cathode, and at least one organic-compound layer that is provided between the anode and the cathode, with at least one layer of the at least one organic-compound layer being an organic luminescent layer,
wherein the organic luminescent layer comprises at least one host material and at least two luminescent materials, and at least one of the luminescent materials is a metal complex having a tridentate or higher polydentate chain ligand.

2. The organic electroluminescent device as claimed in claim 1, wherein a metal ion in the metal complex is selected from the group consisting of platinum, iridium, rhenium, palladium, rhodium, ruthenium, and copper ions.

3. The organic electroluminescent device as claimed in claim 1, wherein the metal complex is a metal complex that emits phosphorescence.

4. The organic electroluminescent device as claimed in claim 1, wherein at least two of the luminescent materials are metal complexes each having a tridentate or higher polydentate ligand.

5. The organic electroluminescent device as claimed in claim 1, wherein the metal complex is a compound represented by formula (1): 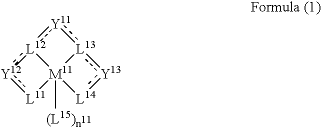
wherein, M¹¹ represents a metal ion; L¹¹, L¹², L¹³, L¹⁴, and L¹⁵ each represent a ligand to coordinate to M¹¹; L¹¹ and L¹⁴ do not combine together via an atomic group, to form a cyclic ligand; L¹⁵ does not bond to both L¹¹ and L¹⁴, to form a cyclic ligand; Y¹¹, Y¹², and Y¹³ each represent a linking group, a single bond, or a double bond; a bond between L¹¹ and Y¹², a bond between Y¹² and L¹², a bond between L¹² and Y¹¹, a bond between Y¹¹ and L¹³, a bond between L¹³ and Y¹³, and a bond between Y¹³ and L¹⁴ each represent a single bond, or a double bond; n¹¹ represents 0 to 4.

6. The organic electroluminescent device as claimed in claim 1, wherein the metal complex is a compound represented by formula (2): 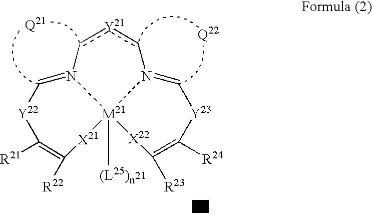
wherein, M²¹ represents a metal ion; Y²¹ represents a linking group, a single bond, or a double bond; Y²² and Y²³ each represent a single bond or a linking group; Q²¹ and Q²² each represent an atomic group necessary to form a nitrogen-containing heterocycle; a bond between Y²¹ and the ring formed with Q²¹, and a bond between Y²¹ and the ring formed with Q²² each represent a single bond, or a double bond; X²¹ and X²² each represent an oxygen atom, a sulfur atom, or a substituted or unsubstituted nitrogen atom; R²³, R²², R²³, and R²⁴ each represent a hydrogen atom, or a substituent; R²¹ and R²², and R²³ and R²⁴, respectively, may bond to each other to form a ring; L²⁵ represents a ligand to coordinate to M²¹; n²¹ represents an integer of 0 to 4.

7. The organic electroluminescent device as claimed in claim 6, wherein the ring formed with Q²¹ and the ring formed with Q²² each are a pyridine ring, and Y²¹ represents a linking group composed of at least one atom.

8. The organic electroluminescent device as claimed in claim 6, wherein the ring formed with Q²¹ and the ring formed with Q²² each are a pyridine ring, Y²¹ represents a single bond or a double bond, and X²¹ and X²² each represent a sulfur atom or a substituted or unsubstituted nitrogen atom.

9. The organic electroluminescent device as claimed in claim 6, wherein the ring formed with Q²¹ and the ring formed with Q²² each are a 5-membered nitrogen-containing heterocycle.

10. The organic electroluminescent device as claimed in claim 6, wherein the ring formed with Q²¹ and the ring formed with Q²² each are a 6-membered nitrogen-containing heterocycle containing at least two nitrogen atoms.

11. The organic electroluminescent device as claimed in claim 1, wherein the metal complex is a compound represented by formula (9): 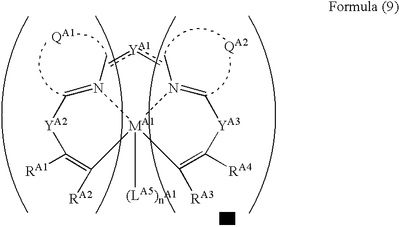
wherein, M^{A1} represents a metal ion; Q^{A1} and Q^{A2} each represent an atomic group necessary to form a nitrogen-containing heterocycle; R^{A1}, R^{A2}, R^{A3}, and R^{A4} each represent a hydrogen atom, or a substituent; R^{A1} and R^{A2}, and R^{A3} and R^{A4}, respectively, may bond to each other to form a ring; Y^{A2} and Y^{A3} each represent a linking group or a single bond; Y^{A1} represents a linking group, a single bond, or a double bond, for linking two bidentate ligands in parentheses together; L^{A5} represents a ligand to coordinate to M^{A1}; n^{A1} represents an integer of 0 to 4.

12. The organic electroluminescent device as claimed in claim 11, wherein the metal complex is a compound represented by formula (11): 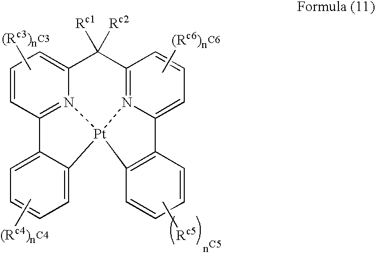
wherein, R^{C1} and R^{C2} each represent a hydrogen atom or a substituent; R^{C3}, R^{C4}, R^{C5}, and R^{C6}, each represent a substituent; n^{C3} and n^{C6} each represent an integer of 0 to 3; n^{C4} and n^{C5} each represent an integer of 0 to 4; when a plurality of R^{C3}, R^{C 4}, R^{C5}, or R^{C6} exists, the respective R^{C3}s, R^{C4}s, R^{C5}s, or R^{C6}s may be the same or different from each other, and, respectively, the R^{C3}s, R^{C4}s, R^{C5}s, or R^{C6}s may bond to each other to form a ring.

13. The organic electroluminescent device as claimed in claim 1, wherein the metal complex is a compound represented by formula (10): 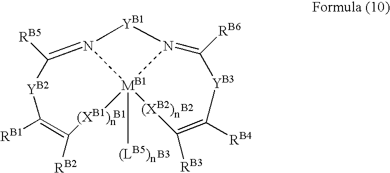
wherein, M^{B1} represents a metal ion; Y^{B1} represents a linking group; Y^{B2} and Y^{B3} each represent a linking group or a single bond; X^{B1} and X^{B2} each represent an oxygen atom, a sulfur atom, or a substituted or unsubstituted nitrogen atom; n^{B1} and n^{B2} each represent an integer of 0 to 1; R^{B1}, R^{B2}, R^{B3}, R^{B4}, R^{B5}, and R^{B6} each represent a hydrogen atom, or a substituent; R^{B1} and R^{B2}, and R^{B3} and R^{B4}, respectively, may bond to each other to form a ring; L^{B5} represents a ligand to coordinate to M^{B1}; n^{B3} represents an integer of 0 to 4; and Y^{B1} does not link to R^{B5} or R^{B6}.

14. The organic electroluminescent device as claimed in claim 1, wherein the metal complex is a compound represented by formula (12): 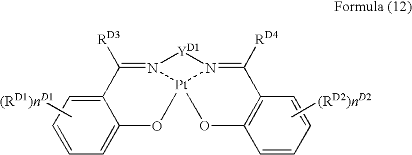
wherein, R^{D3} and R^{D4} each represent a hydrogen atom or a substituent; R^{D1} and R^{D2} each represent a substituent; n^{D1} and n^{D2} each represent an integer of 0 to 4; when a plurality of R^{D1} exists, R^{D1}s may be the same or different from each other, and R^{D1}s may bond to each other to form a ring; when a plurality of R^{D2} exists, R^{D2}s may be the same or different from each other, and R^{D2}s may bond to each other to form a ring; and Y^{D1} represents a vinyl group that substitutes with 1- and 2-positions, a phenylene group, a pyridine ring, a pyrazine ring, a pyrin-idine ring, or a methylene group having 1 to 8 carbon atoms.

15. The organic electroluminescent device as claimed in claim 1, wherein the metal complex is a compound represented by formula (8): 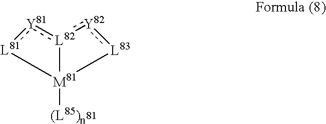
wherein, M⁸¹ represents a metal ion; L⁸¹, L⁸², L⁸³, and L⁸⁵ each represent a ligand to coordinate to M⁸¹; L⁸¹ and L⁸³ do not combine together via an atomic group, to form a cyclic ligand or a tetradentate or higher-polydentate ligand; L⁸⁵ does not directly bond to L⁸¹ or L⁸³, but bonds to via the metal; Y⁸¹ and Y⁸² each represent a linking group, a single bond, or a double bond; n⁸¹ represents an integer of 0 to 3.

16. The organic electroluminescent device as claimed in claim 15, wherein L⁸¹, L⁸², and L⁸³ each represent an aromatic carbocycle or heterocycle to coordinate to M⁸¹ via a carbon atom, or a nitrogen-containing heterocycle to coordinate to M⁸¹ via a nitrogen atom, and at least one of L⁸¹, L⁸², and L⁸³ is said nitrogen-containing heterocycle.

17. The organic electroluminescent device as claimed in claim 1, wherein the metal complex is a compound represented by formula (X1): 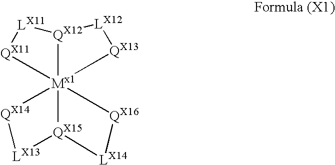
wherein, M^{X1} represents a metal ion; Q^{X11}, Q^{X12}, Q^{X13}, Q^{X14}, Q^{X15}, and Q^{X16} each represent an atom to coordinate to M^{X1} or an atomic group having an atom to coordinate to M^{X1}; L^{X11}, L^{X12}, L^{X13}, and L^{X14} each represent a single bond, a double bond, or a linking group; an atomic group consisted of Q^{X11}-L^{X11}-Q^{X12}-L^{X12}-Q^{X13} and an atomic group consisted of Q^{X14}-L^{X13}-Q^{X15}-L^{X14}-Q^{X16} each represent a tridentate ligand; and a bond between M^{X1} and Q^{X11}, a bond between M^{X1} and Q^{X12}, a bond between M^{X1} and Q^{X13}, a bond between M^{X1} and Q^{X14}, a bond between M^{X1} and Q^{X15}, and a bond between M^{X1} and Q^{X16}, each are a coordinate bond or a covalent bond.

18. The organic electroluminescent device as claimed in claim 17, wherein the metal complex represented by formula (X1) is a compound represented by formula (X2): 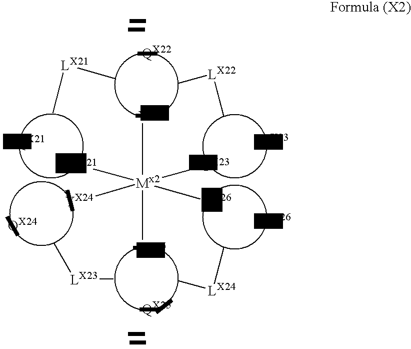
wherein, M^{X2} represents a metal ion; Y^{X21}, Y^{X22}, Y^{X23}, Y^{X24}, Y^{X25}, and Y^{X26} each represent an atom to coordinate to M^{X2}; each of Q^{X21}, Q^{X22}, Q^{X23}, Q^{X24}, Q^{X25}, and Q^{X26} respectively represents an atomic group necessary to form an aromatic ring or heterocyclic ring together with each of Y^{X21}, Y^{X22}, Y^{X23}, Y^{X24}, Y^{X25}, and Y^{X26}, respectively; L^{X21}, L^{X22}, L^{X23}, and L^{X24} each represent a single bond, a double bond, or a linking group; and a bond between M^{X2} and Y^{X21}, a bond between M^{X2} and Y^{X22}, a bond between M^{X2} and Y^{X23}, a bond between M^{X2} and Y^{X24}, a bond between M^{X2} and Y^{X25}, and a bond between M^{X2} and Y^{X26} each are a coordinate bond or a covalent bond.

19. The organic electroluminescent device as claimed in claim 17, wherein the metal complex represented by formula (X1) is a compound represented by formula (X3): 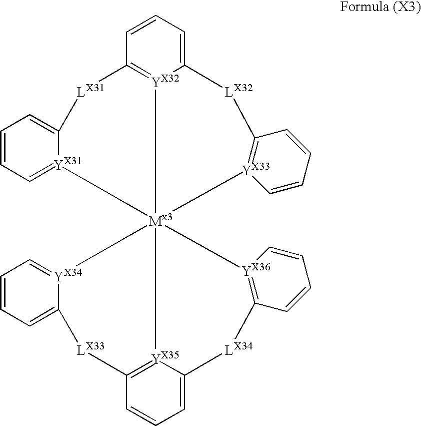
wherein, M^{X3} represents a metal ion; Y^{X31}, Y^{X32}, Y^{X33}, Y^{X34}, Y^{X35}, and Y^{X36} each represent a carbon atom, a nitrogen atom, or a phosphorus atom; L^{X31}, L^{X32}, L^{X33}, and L^{X34} each represent a single bond, a double bond, or a linking group; and a bond between M^{X3} and Y^{X31}, a bond between M^{X3} and Y^{X32}, a bond between M^{X3} and Y^{X33}, a bond between M^{X3} and y^{X34}, a bond between M^{X3} and Y^{X35}, and a bond between M^{X3} and y^{X36} each are a coordinate bond or a covalent bond.

20. The organic electroluminescent device as claimed in claim 1, wherein the host material of the luminescent layer consists of two or more kinds of compounds.
